(19) United States
(12) Patent Application Publication
(10) Pub. No.: US 2025/0113668 A1
(43) Pub. Date: Apr. 3, 2025

(54) A MICRO LED PANEL WITH RE-GROWTH LAYER AND MANUFACTURING METHOD THEREOF

(71) Applicant: Jade Bird Display (Shanghai) Limited, Pudong New Area, Shanghai (CN)

(72) Inventors: Yuankun ZHU, Shanghai (CN); Shuang ZHAO, Shanghai (CN); Deshuai LIU, Shanghai (CN)

(73) Assignee: Jade Bird Display (Shanghai) Limited, Pudong New Area, Shanghai (CN)

(21) Appl. No.: 18/832,132

(22) PCT Filed: Jan. 31, 2022
(86) PCT No.: PCT/CN2022/075280

§ 371 Date: Jul. 23, 2024

(51) Int. Cl. H10H 20/821; H10H 20/80; H10H 20/812; H10H 29/80; H10H 29/85

(52) U.S. Cl. CPC H10H 20/821; H10H 20/812; H10H 20/872; H10H 29/857; H10H 29/942

(57) ABSTRACT

A micro LED panel having a micro LED array and the system and method to manufacture the micro LED panel are provided by the present disclosure. The micro LED array includes at least one micro LED structure. The micro LED structure at least includes: a mesa structure and a photonic crystal structure array. The photonic crystal structure array formed through the mesa structure from top to bottom, thereby realizing higher directional light emission, simpler structure and lower cost.

### TECHNICAL FIELD

The present disclosure generally relates to light emitting diode (LED) technology and, more particularly, to a micro LED panel and a method of manufacturing the micro LED structure.

### BACKGROUND

Display technologies are becoming increasingly important in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices.

Inorganic micro light emitting diodes are of increasing importance because of their use in various applications including self-emissive micro-displays, visible light communications and opto-genetics. The micro LEDs show higher output performance than conventional LEDs due to better strain relaxation, improved light extraction efficiency, and uniform current spreading. The micro LEDs also exhibit improved thermal effects, and operate at a higher current density, fast response rate, larger work temperature range, higher resolution, color gamut, and contrast and lower power consumption as compared with conventional LEDs.

To achieve higher pixel density, the size of the micro LEDs is reduced to less than 200 nm. However, the efficiency and the carrier lifetime of the micro LED array based device degrade drastically with the reduced micro LED size to a large extent, by surface recombination and poor p-type conduction induced by top-down etching. The performance of micro LEDs also suffers severely from quantum-confined stark effect, particularly due to the strain-induced polarization field, which leads to unstable operation, and significant variations in emission wavelengths with increasing current. Additionally, with the decrease of the micro LED diameter, a large number of surface states and defects are formed at the surface of the micro LED structure by Inductively Coupled Plasma (ICP) etching, which increases the non-radiation recombination at the surface of the micro LED structures.

Additionally, the emission of the conventional micro LED structure is mainly distributed at any direction which exhibits poor directional emission and reduces the light intensity along the vertical direction. To realize the directional emission of the micro LED structure, extra reflective structures are configured around the mesa of the micro LED structure and at the bottom of the mesa, so as to reflect the emission light to a same direction, which causes a complex manufacturing process and increases the cost of the micro LED.

Furthermore, in the micro LED array based device, one micro LED is conventionally used as one pixel such as in monolithic micro LED array panel. However, the micro LED structure with smaller diameter shows lower external quantum efficiency (EQE), which reduces the light efficiency of each pixel.

The above content is only used to assist in understanding the technical solutions of the present application, and does not constitute an admission that the above is prior art.

### SUMMARY

There is a need for improved display designs that improve upon, and help to address the shortcomings of conventional display systems, such as those described above. In particular, there is a need for display panels with improved efficiency with better images.

In order to overcome the drawback mentioned above, the present invention provides a micro LED panel, to improve the light emitting efficiency, to avoid crosstalk, to minimize the surface carrier loss, and to optimize the quantum well sidewall area.

To achieve the above objectives, some exemplary embodiments of the present disclosure provide a micro LED panel including a micro LED array, comprising:
at least a micro LED structure, wherein the micro LED structure at least comprises:
   a mesa structure, wherein the mesa structure from bottom to top comprises: a first type semiconductor layer, a light emitting layer and a second type semiconductor layer; and,
   a photonic crystal structure array comprising a plurality of photonic crystal structures, formed through the mesa structure from top to bottom, wherein a gap is between adjacent photonic crystal structures.

In some exemplary embodiments or any combination of exemplary embodiments of the micro-LED panel, top of the photonic crystal structures are top of the mesa structure and bottom of the photonic crystal structures are bottom of the mesa structure.

In some exemplary embodiments or any combination of exemplary embodiments of the micro-LED panel, the photonic crystal structure is a one dimensional nano-structure.

In some exemplary embodiments or any combination of exemplary embodiments of the micro-LED panel, a plurality of the one dimensional nano-structures are distributed in the photonic crystal structure array.

In some exemplary embodiments or any combination of exemplary embodiments of the micro-LED panel, the one dimensional nano-structures are formed in the mesa structure along a light emitting direction of the mesa structure.

In some exemplary embodiments or any combination of exemplary embodiments of the micro-LED panel, diameter of the one dimensional nano-structures is not more than 1000 nm.

In some exemplary embodiments or any combination of exemplary embodiments of the micro-LED panel, the one dimensional nano-structures are formed perpendicular to the light emitting layer.

In some exemplary embodiments or any combination of exemplary embodiments of the micro-LED panel, a dielectric layer is filled in the gap between the adjacent photonic crystal structures.

In some exemplary embodiments or any combination of exemplary embodiments of the micro-LED panel, the dielectric layer is further formed on sidewall of the mesa structure.

In some exemplary embodiments or any combination of exemplary embodiments of the micro-LED panel, the dielectric layer is fully filled in space between adjacent micro LED structures.

In some exemplary embodiments or any combination of exemplary embodiments of the micro-LED panel, the dielectric layer is transparent and electrically isolated.

In some exemplary embodiments or any combination of exemplary embodiments of the micro-LED panel, width of the mesa structure is not more than 3 μm.

In some exemplary embodiments or any combination of exemplary embodiments of the micro-LED panel, the light emitting layer comprises several stacked pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the first semiconductor layer is monocrystal and material of the second semiconductor layer is monocrystal.

In some exemplary embodiments or any combination of exemplary embodiments of the micro-LED panel, a top contact is formed on and electrically connected to top of the mesa structure, and a top conductive layer is formed on the top contact and the top of the mesa structure.

In some exemplary embodiments or any combination of exemplary embodiments of the micro-LED panel, the top conductive layer is transparent.

Some exemplary embodiments of the present disclosure provide a method for manufacturing the micro LED panel, comprising the following steps:
step 1, supplying a semiconductor substrate with an epitaxial structure; the epitaxial structure from top down comprises: a first type epitaxial layer, a light emitting layer and a second type epitaxial layer;
step 2, forming a bottom contact layer and a bottom connected layer in order on the top surface of the first type epitaxial layer;
step 3, bonding the bottom connected layer with an IC backplane by turning the semiconductor substrate upside down; then, removing the semiconductor substrate;
step 4, forming a photonic crystal structure array comprising a plurality of photonic crystal structures by etching the epitaxial structure;
step 5, forming an space to define a mesa structure by etching the photonic crystal structure array, the bottom contact layer and the bottom connected layer from top to bottom;
step 6, forming a dielectric layer on sidewall of the photonic crystal structures; and
step 7, forming a top contact and a top conductive layer on top of the dielectric layer and top of the mesa structure.

In some exemplary embodiments or any combination of exemplary embodiments of the method of manufacturing the micro-LED panel, in step 6, the dielectric layer is further formed on sidewall of the mesa structure.

In some exemplary embodiments or any combination of exemplary embodiments of the method of manufacturing the micro-LED panel, in step 7, the top conductive layer is formed in the space between adjacent mesa structures.

In some exemplary embodiments or any combination of exemplary embodiments of the method of manufacturing the micro-LED panel, the dielectric layer is further fully filled in the space between adjacent mesa structures.

In some exemplary embodiments or any combination of exemplary embodiments of the method of manufacturing the micro-LED panel, in step 7, the top conductive layer is formed on the top of the dielectric layer.

In some exemplary embodiments or any combination of exemplary embodiments of the method of manufacturing the micro-LED panel, in step 4, top of the photonic crystal structures are top of the mesa structure and bottom of the photonic crystal structures are bottom of the mesa structure

In some exemplary embodiments or any combination of exemplary embodiments of the method of manufacturing the micro-LED panel, in step 4, the photonic crystal structure is a one dimensional nano-structure.

In some exemplary embodiments or any combination of exemplary embodiments of the method of manufacturing the micro-LED panel, the one dimensional nano-structures are formed along the light emitting direction of the mesa structure.

In some exemplary embodiments or any combination of exemplary embodiments of the method of manufacturing the micro-LED panel, the one dimensional nano-structures are formed perpendicular to the light emitting layer.

In some exemplary embodiments or any combination of exemplary embodiments of the method of manufacturing the micro-LED panel, diameter of the one dimensional nano-structures is not more than 1000 nm.

In some exemplary embodiments or any combination of exemplary embodiments of the method of manufacturing the micro-LED panel, in step 5, width of the mesa structure is not more than 3 μm.

In some exemplary embodiments or any combination of exemplary embodiments of the method of manufacturing the micro-LED panel, in step 6, width of the mesa structure is not more than 3 μm.

In some exemplary embodiments or any combination of exemplary embodiments of the method of manufacturing the micro-LED panel, in step 1, material of the first epitaxial layer is monocrystal and material of the second epitaxial layer is monocrystal.

In some exemplary embodiments or any combination of exemplary embodiments of the method of manufacturing the micro-LED panel, in step 7, the top contact is firstly formed on the top of the photonic crystal structure array and electrically connected to at least one of the photonic crystal structure; and then, the top conductive layer is formed on the top contact and top of the mesa structure.

Some exemplary embodiments of the present disclosure provide a micro LED panel including a micro LED array comprising:
at least a micro LED structure, wherein the micro LED structure at least comprises:
   a mesa structure, wherein the mesa structure from bottom to top comprises: a first type semiconductor layer, a light emitting layer and a second type semiconductor layer; and,
   a photonic crystal structure array comprising a plurality of photonic crystal structures, formed through the mesa structure from top to bottom, wherein, a gap is between adjacent photonic crystal structures; and,
   a re-growth layer, formed on at least part of sidewall of the mesa structure.

In some exemplary embodiments or any combination of exemplary embodiments of the micro-LED panel, top of the photonic crystal structures are top of the mesa structure and bottom of the photonic crystal structures are bottom of the mesa structure.

In some exemplary embodiments or any combination of exemplary embodiments of the micro-LED panel, the photonic crystal structure is a one dimensional nano-structure.

In some exemplary embodiments or any combination of exemplary embodiments of the micro-LED panel, a plurality of the one dimensional nano-structures are distributed in the photonic crystal structure array.

In some exemplary embodiments or any combination of exemplary embodiments of the micro-LED panel, the one dimensional nano-structures are formed in the mesa structure along a light emitting direction of the mesa structure.

In some exemplary embodiments or any combination of exemplary embodiments of the micro-LED panel, diameter of the one dimensional nano-structures is not more than 1000 nm.

In some exemplary embodiments or any combination of exemplary embodiments of the micro-LED panel, the one dimensional nano-structures are formed perpendicular to the light emitting layer.

In some exemplary embodiments or any combination of exemplary embodiments of the micro-LED panel, a dielectric layer is filled in the gap between the adjacent photonic crystal structures.

In some exemplary embodiments or any combination of exemplary embodiments of the micro-LED panel, the dielectric layer is filled in space between adjacent micro LED structures.

In some exemplary embodiments or any combination of exemplary embodiments of the micro-LED panel, the dielectric layer is transparent and electrically isolated.

In some exemplary embodiments or any combination of exemplary embodiments of the micro-LED panel, width of the mesa structure is not more than 3 μm.

In some exemplary embodiments or any combination of exemplary embodiments of the micro-LED panel, the light emitting layer comprises several stacked pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the first semiconductor layer is monocrystal and material of the second semiconductor layer is monocrystal.

In some exemplary embodiments or any combination of exemplary embodiments of the micro-LED panel, the re-growth layer is formed at least on part of sidewall of the light emitting layer.

In some exemplary embodiments or any combination of exemplary embodiments of the micro-LED panel, the re-growth layer is formed on whole sidewall of the light emitting layer.

In some exemplary embodiments or any combination of exemplary embodiments of the micro-LED panel, the re-growth layer is formed at least part of sidewall of the first type epitaxial layer, whole sidewall of the light emitting layer and at least part of sidewall of the first type epitaxial layer.

In some exemplary embodiments or any combination of exemplary embodiments of the micro-LED panel, the re-growth layer is further formed at sidewall of the photonic crystal structures.

In some exemplary embodiments or any combination of exemplary embodiments of the micro-LED panel, the re-growth layer is fully filled in the gap between the adjacent photonic crystal structures.

In some exemplary embodiments or any combination of exemplary embodiments of the micro-LED panel, the re-growth layer is fully filled in a gap between the adjacent mesa structures.

In some exemplary embodiments or any combination of exemplary embodiments of the micro-LED panel, material of the re-growth layer with intrinsic doped ions is the same as material of the first type semiconductor layer and/or material of the second type semiconductor layer but without intentional doping ions.

In some exemplary embodiments or any combination of exemplary embodiments of the micro-LED panel, material of the re-growth layer is one or more of GaP, AlP, GaAs, InP, AlInP, GaInP, AlN, GaN, and/or InN.

In some exemplary embodiments or any combination of exemplary embodiments of the micro-LED panel, material of the re-growth layer is monocrystal.

In some exemplary embodiments or any combination of exemplary embodiments of the micro-LED panel, a band gap of the re-growth layer is greater than a band gap of the light emitting layer.

In some exemplary embodiments or any combination of exemplary embodiments of the micro-LED panel, thickness of the re-growth layer is less than thickness of the light emitting layer.

In some exemplary embodiments or any combination of exemplary embodiments of the micro-LED panel, thickness of the re-growth layer is not more than 100 nm.

In some exemplary embodiments or any combination of exemplary embodiments of the micro-LED panel, resistance of the re-growth layer is higher than resistance of the light emitting layer.

In some exemplary embodiments or any combination of exemplary embodiments of the micro-LED panel, the re-growth layer is not electrically conductive.

In some exemplary embodiments or any combination of exemplary embodiments of the micro-LED panel, a top contact is formed on and electrically connected to top of the mesa structure, and a top conductive layer is formed on the top contact and the top of the mesa structure.

In some exemplary embodiments or any combination of exemplary embodiments of the micro-LED panel, the top conductive layer is transparent.

Some exemplary embodiments of the present disclosure provide a method for manufacturing the micro LED panel, comprising the following steps:
step 1, supplying a semiconductor substrate with an epitaxial structure;
step 2, forming a photonic crystal structure array comprising a plurality of photonic crystal structures in the epitaxial structure by etching the epitaxial structure;
step 3, forming a space to define a mesa structure by etching the photonic crystal structures;
step 4, forming a re-growth layer on sidewall of the photonic crystal structures;
step 5, forming a bottom contact on top of the photonic crystal structure array;
step 6, forming a dielectric layer on the top of the photonic crystal structure array, on top of the re-growth layer and covering the bottom contact;
step 7, forming a bottom connected structure on top of the bottom contact;
step 8, bonding the bottom connected structure with an IC backplane by turning the semiconductor substrate upside down; then, removing the semiconductor substrate; and
step 9, forming a top contact and a top conductive layer on top of the dielectric layer and top of the mesa structure.

In some exemplary embodiments or any combination of exemplary embodiments of the method of manufacturing the micro-LED panel, in step 6, the dielectric layer is further formed further fully filled in the space between adjacent mesa structures.

In some exemplary embodiments or any combination of exemplary embodiments of the method of manufacturing the micro-LED panel, in step 2, the photonic crystal structure is a one dimensional nano-structure.

In some exemplary embodiments or any combination of exemplary embodiments of the method of manufacturing the micro-LED panel, the one dimensional nano-structures are formed in the mesa structure along a light emitting direction of the mesa structure.

In some exemplary embodiments or any combination of exemplary embodiments of the method of manufacturing the micro-LED panel, the one dimensional nano-structures are formed perpendicular to the light emitting layer.

In some exemplary embodiments or any combination of exemplary embodiments of the method of manufacturing the micro-LED panel, diameter of the one dimensional nano-structures is not more than 1000 nm.

In some exemplary embodiments or any combination of exemplary embodiments of the method of manufacturing the micro-LED panel, step 1, width of the mesa structure is not more than 3 μm.

In some exemplary embodiments or any combination of exemplary embodiments of the method of manufacturing the micro-LED panel, in step 4, material of the re-growth layer with intrinsic doped ions is the same as material of the first type semiconductor layer and/or material of the second type semiconductor layer but without intentional doping ions.

In some exemplary embodiments or any combination of exemplary embodiments of the method of manufacturing the micro-LED panel, material of the re-growth layer is monocrystal.

In some exemplary embodiments or any combination of exemplary embodiments of the method of manufacturing the micro-LED panel, material of the re-growth layer is one or more of GaP, AlP, GaAs, InP, AlInP, GaInP, AlN, GaN, and/or InN.

In some exemplary embodiments or any combination of exemplary embodiments of the method of manufacturing the micro-LED panel, a band gap of the re-growth layer is greater than a band gap of the light emitting layer; thickness of the re-growth layer is less than the thickness of the light emitting layer; and, resistance of the re-growth layer is higher than resistance of the light emitting layer.

Some exemplary embodiments of the present disclosure provide a method for manufacturing a micro LED panel, comprising the following steps:
step 1, supplying a semiconductor substrate with an epitaxial structure;
step 2, forming a photonic crystal structure array comprising a plurality of photonic crystal structures in the epitaxial structure by etching the epitaxial structure;
step 3, forming a space to define a mesa structure by etching the photonic crystal structures;
step 4, forming a re-growth layer on sidewall of the photonic crystal structures and fully filled in the space between adjacent mesa structures;
step 5, forming a top contact on top of the photonic crystal structure array;
step 6, forming a dielectric layer on top of the mesa structure, on top of the bottom contact and on top of the re-growth layer;
step 7, forming a bottom connected structure on the top of the bottom contact;
step 8, bonding the bottom connected structure with an IC backplane by turning the semiconductor substrate upside down; then, removing the semiconductor substrate; and
step 9, forming a top contact and a top conductive layer on top of the dielectric layer and the top of the mesa structure.

In some exemplary embodiments or any combination of exemplary embodiments of the method of manufacturing the micro-LED panel, in step 2, the photonic crystal structure is a one dimensional nano-structure.

In some exemplary embodiments or any combination of exemplary embodiments of the method of manufacturing the micro-LED panel, the one dimensional nano-structures are formed in the mesa structure along a light emitting direction of the mesa structure.

In some exemplary embodiments or any combination of exemplary embodiments of the method of manufacturing the micro-LED panel, the one dimensional nano-structures are formed perpendicular to the light emitting layer.

In some exemplary embodiments or any combination of exemplary embodiments of the method of manufacturing the micro-LED panel, diameter of the one dimensional nano-structures is not more than 1000 nm.

In some exemplary embodiments or any combination of exemplary embodiments of the method of manufacturing the micro-LED panel, step 1, width of the mesa structure is not more than 3 μm.

In some exemplary embodiments or any combination of exemplary embodiments of the method of manufacturing the micro-LED panel, in step 4, material of the re-growth layer with intrinsic doped ions is the same as material of the first type semiconductor layer and/or material of the second type semiconductor layer but without intentional doping ions.

In some exemplary embodiments or any combination of exemplary embodiments of the method of manufacturing the micro-LED panel, material of the re-growth layer is monocrystal.

In some exemplary embodiments or any combination of exemplary embodiments of the method of manufacturing the micro-LED panel, material of the re-growth layer is one or more of GaP, AlP, GaAs, InP, AlInP, GaInP, AlN, GaN, and/or InN.

In some exemplary embodiments or any combination of exemplary embodiments of the method of manufacturing the micro-LED panel, a band gap of the re-growth layer is greater than a band gap of the light emitting layer.

In some exemplary embodiments or any combination of exemplary embodiments of the method of manufacturing the micro-LED panel, thickness of the re-growth layer is less than thickness of the light emitting layer.

In some exemplary embodiments or any combination of exemplary embodiments of the method of manufacturing the micro-LED panel, resistance of the re-growth layer is higher than resistance of the light emitting layer.

Some exemplary embodiments of the present disclosure provide a micro LED panel including a micro LED array, comprising:
at least one micro LED structure, wherein the micro LED structure at least comprises:
   a mesa structure, wherein the mesa structure from bottom to top comprises: a first type semiconductor layer, a light emitting layer and a second type semiconductor layer; and,
   a photonic crystal structure array comprising a plurality of photonic crystal structures, formed through the mesa structure from top to bottom, wherein a gap is between the adjacent photonic crystal structures,
   wherein the photonic crystal structure array comprises a center photonic crystal structure, and other photonic crystal structures formed around the center photonic crystal structure.

In some exemplary embodiments or any combination of exemplary embodiments of the micro-LED panel, the micro LED structure further comprises a top contact, formed on top of the center photonic crystal structure.

In some exemplary embodiments or any combination of exemplary embodiments of the micro-LED panel, top of the photonic crystal structures are top of the mesa structure and bottom of the photonic crystal structures are bottom of the mesa structure.

In some exemplary embodiments or any combination of exemplary embodiments of the micro-LED panel, the photonic crystal structure is a one dimensional nano-structure.

In some exemplary embodiments or any combination of exemplary embodiments of the micro-LED panel, a plurality of the one dimensional nano-structures are distributed in the photonic crystal structure array.

In some exemplary embodiments or any combination of exemplary embodiments of the micro-LED panel, the one dimensional nano-structures are formed in the mesa structure along a light emitting direction of the mesa structure.

In some exemplary embodiments or any combination of exemplary embodiments of the micro-LED panel, diameter of the one dimensional nano-structures is not more than 1000 nm.

In some exemplary embodiments or any combination of exemplary embodiments of the micro-LED panel, the one dimensional nano-structures are formed perpendicular to the light emitting layer.

In some exemplary embodiments or any combination of exemplary embodiments of the micro-LED panel, a dielectric layer is filled in the gap between the adjacent photonic crystal structures.

In some exemplary embodiments or any combination of exemplary embodiments of the micro-LED panel, the dielectric layer is further formed on sidewall of the mesa structure.

In some exemplary embodiments or any combination of exemplary embodiments of the micro-LED panel, the dielectric layer is fully filled in space between adjacent micro LED structures.

In some exemplary embodiments or any combination of exemplary embodiments of the micro-LED panel, the dielectric layer is transparent and electrically isolated.

In some exemplary embodiments or any combination of exemplary embodiments of the micro-LED panel, width of the mesa structure is not more than 3 μm.

In some exemplary embodiments or any combination of exemplary embodiments of the micro-LED panel, the light emitting layer comprises several stacked pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the first semiconductor layer is monocrystal and material of the second semiconductor layer is monocrystal.

In some exemplary embodiments or any combination of exemplary embodiments of the micro-LED panel, a top conductive layer is formed on the top contact and top of the mesa structure.

In some exemplary embodiments or any combination of exemplary embodiments of the micro-LED panel, the top conductive layer is transparent.

Some exemplary embodiments of the present disclosure provide a method for manufacturing a micro LED panel, comprising the following steps:
step 1, supplying a semiconductor substrate with an epitaxial structure, wherein the epitaxial structure from top down comprises: a first type epitaxial layer, a light emitting layer and a second type epitaxial layer;
step 2, forming a bottom contact layer and a bottom connected layer in order on top surface of the first type epitaxial layer;
step 3, bonding the bottom connected layer with an IC backplane by turning the semiconductor substrate upside down; then, removing the semiconductor substrate;
step 4, forming a top contact on top of the second type epitaxial layer;
step 5, forming a mesa structure in the epitaxial structure by etching the epitaxial structure, the bottom contact layer and the bottom connected layer from top to bottom; and, forming a photonic crystal structure array comprising a plurality of photonic crystal structures by etching the epitaxial structure;
step 6, forming a dielectric layer on sidewall of the photonic crystal structures; and
step 7, forming a top conductive layer on surface of the dielectric layer, and top of the mesa structure.

In some exemplary embodiments or any combination of exemplary embodiments of the method of manufacturing the micro-LED panel, in step 6, the dielectric layer is further filled in space between adjacent mesa structures.

In some exemplary embodiments or any combination of exemplary embodiments of the method of manufacturing the micro-LED panel, in step 7, the top conductive layer is formed in space between adjacent mesa structures.

In some exemplary embodiments or any combination of exemplary embodiments of the method of manufacturing the micro-LED panel, in step 6, the dielectric layer is fully filled in the space between the adjacent mesa structures, and the top conductive layer is formed on top of the dielectric layer.

In some exemplary embodiments or any combination of exemplary embodiments of the method of manufacturing the micro-LED panel, in step 5, the photonic crystal structure is a one dimensional nano-structure, and, the one dimensional nano-structures are formed in the mesa structure and along a light emitting direction of the mesa structure.

In some exemplary embodiments or any combination of exemplary embodiments of the method of manufacturing the micro-LED panel, the one dimensional nano-structures are formed perpendicular to the light emitting layer.

In some exemplary embodiments or any combination of exemplary embodiments of the method of manufacturing the micro-LED panel, diameter of the one dimensional nano-structures is not more than 1000 nm.

In some exemplary embodiments or any combination of exemplary embodiments of the method of manufacturing the micro-LED panel, in step 5, width of the mesa structure is not more than 3 μm.

In some exemplary embodiments or any combination of exemplary embodiments of the method of manufacturing the micro-LED panel, in step 1, material of the first epitaxial layer is monocrystal and material of the second epitaxial layer is monocrystal.

Some exemplary embodiments of the present disclosure provide a micro LED panel including a micro LED array, comprising:
at least a micro LED structure, wherein the micro LED structure at least comprises:
   a mesa structure, wherein the mesa structure from bottom to top comprises: a first type semiconductor layer, a light emitting layer and a second type semiconductor layer;
   a photonic crystal structure array comprising a plurality of photonic crystal structures, formed through the mesa structure from top to bottom, wherein a gap is between adjacent photonic crystal structures, and wherein the photonic crystal structure array comprises a center photonic crystal structure, and other photonic crystal structures formed around the center photonic crystal structure; and,
   a re-growth layer, formed on at least part of sidewall of the mesa structure.

In some exemplary embodiments or any combination of exemplary embodiments of the micro-LED panel, the micro LED structure further comprises a top contact, formed on top of the center photonic crystal structure.

In some exemplary embodiments or any combination of exemplary embodiments of the micro-LED panel, top of the photonic crystal structures are top of the mesa structure and bottom of the photonic crystal structures are bottom of the mesa structure.

In some exemplary embodiments or any combination of exemplary embodiments of the micro-LED panel, the photonic crystal structure is a one dimensional nano-structure.

In some exemplary embodiments or any combination of exemplary embodiments of the micro-LED panel, a plurality of the one dimensional nano-structures are distributed in the photonic crystal structure array.

In some exemplary embodiments or any combination of exemplary embodiments of the micro-LED panel, the one dimensional nano-structures are formed in the mesa structure along a light emitting direction of the mesa structure.

In some exemplary embodiments or any combination of exemplary embodiments of the micro-LED panel, diameter of the one dimensional nano-structures is not more than 1000 nm.

In some exemplary embodiments or any combination of exemplary embodiments of the micro-LED panel, the one dimensional nano-structures are formed perpendicular to the light emitting layer.

In some exemplary embodiments or any combination of exemplary embodiments of the micro-LED panel, a dielectric layer is filled in the gap between the adjacent photonic crystal structures.

In some exemplary embodiments or any combination of exemplary embodiments of the micro-LED panel, the dielectric layer is further filled in space between adjacent micro LED structures.

In some exemplary embodiments or any combination of exemplary embodiments of the micro-LED panel, the dielectric layer is transparent and electrically isolated.

In some exemplary embodiments or any combination of exemplary embodiments of the micro-LED panel, width of the mesa structure is not more than 3 μm.

In some exemplary embodiments or any combination of exemplary embodiments of the micro-LED panel, the light emitting layer comprises several stacked pairs of quantum wells.

In some exemplary embodiments or any combination of exemplary embodiments of the micro-LED panel, the light emitting layer has a straight line shape without any bending.

In some exemplary embodiments or any combination of exemplary embodiments of the micro-LED panel, material of the first semiconductor layer is monocrystal and material of the second semiconductor layer is monocrystal.

In some exemplary embodiments or any combination of exemplary embodiments of the micro-LED panel, the re-growth layer is formed at least on part of sidewall of the light emitting layer.

In some exemplary embodiments or any combination of exemplary embodiments of the micro-LED panel, the re-growth layer is formed on whole sidewall of the light emitting layer.

In some exemplary embodiments or any combination of exemplary embodiments of the micro-LED panel, the re-growth layer is formed at least part of sidewall of the first type epitaxial layer, whole sidewall of the light emitting layer and at least part of sidewall of the first type epitaxial layer.

In some exemplary embodiments or any combination of exemplary embodiments of the micro-LED panel, the re-growth layer is further formed at sidewall of the photonic crystal structures.

In some exemplary embodiments or any combination of exemplary embodiments of the micro-LED panel, the re-growth layer is fully filled in the gap between the adjacent photonic crystal structures.

In some exemplary embodiments or any combination of exemplary embodiments of the micro-LED panel, material of the re-growth layer with intrinsic doped ions is the same as material of the first type semiconductor layer and/or material of the second type semiconductor layer but without intentional doping ions.

In some exemplary embodiments or any combination of exemplary embodiments of the micro-LED panel, material of the re-growth layer is one or more of GaP, AlP, GaAs, InP, AlInP, GaInP, AlN, GaN, and/or InN.

In some exemplary embodiments or any combination of exemplary embodiments of the micro-LED panel, material of the re-growth layer is monocrystal.

In some exemplary embodiments or any combination of exemplary embodiments of the micro-LED panel, a band gap of the re-growth layer is greater than a band gap of the light emitting layer.

In some exemplary embodiments or any combination of exemplary embodiments of the micro-LED panel, thickness of the re-growth layer is less than thickness of the light emitting layer.

In some exemplary embodiments or any combination of exemplary embodiments of the micro-LED panel, thickness of the re-growth layer is not more than 100 nm.

In some exemplary embodiments or any combination of exemplary embodiments of the micro-LED panel, resistance of the re-growth layer is higher than resistance of the light emitting layer.

In some exemplary embodiments or any combination of exemplary embodiments of the micro-LED panel, the re-growth layer is not electrically conductive.

In some exemplary embodiments or any combination of exemplary embodiments of the micro-LED panel, a top conductive layer is formed on the top contact and top of the mesa structure.

In some exemplary embodiments or any combination of exemplary embodiments of the micro-LED panel, the top conductive layer is transparent.

Some exemplary embodiments of the present disclosure provide a method for manufacturing a micro LED panel, comprising the following steps:
step 1, supplying a semiconductor substrate with an epitaxial structure, wherein the epitaxial structure from top down comprises: a first type epitaxial layer, a light emitting layer and a second type epitaxial layer;
step 2, forming a bottom contact on top of the epitaxial structure;
step 3, forming a mesa structure by patterning the epitaxial structure;
step 4, forming a photonic crystal structure array comprising a plurality of photonic crystal structures in the mesa structure;
step 5, forming a re-growth layer on sidewall of the photonic crystal structures;
step 6, forming a dielectric layer on top of the mesa structure, on top of the re-growth layer and covering the bottom contact;
step 7, forming a bottom connected structure on top of the bottom contact;
step 8, bonding the bottom connected structure with an IC backplane by turning the semiconductor substrate upside down; then, removing the semiconductor substrate; and
step 9, forming a top contact and a top conductive layer on top of the dielectric layer, on the top of the re-growth layer and on the top of the mesa structure.

In some exemplary embodiments or any combination of exemplary embodiments of the method of manufacturing the micro-LED panel, in step 6, the dielectric layer is further fully filled in space between adjacent mesa structures.

In some exemplary embodiments or any combination of exemplary embodiments of the method of manufacturing the micro-LED panel, in step 4, the photonic crystal structure is a one dimensional nano-structure.

In some exemplary embodiments or any combination of exemplary embodiments of the method of manufacturing the micro-LED panel, the one dimensional nano-structures are formed in the mesa structure along a light emitting direction of the mesa structure.

In some exemplary embodiments or any combination of exemplary embodiments of the method of manufacturing the micro-LED panel, the one dimensional nano-structures are formed perpendicular to the light emitting layer.

In some exemplary embodiments or any combination of exemplary embodiments of the method of manufacturing the micro-LED panel, diameter of the one dimensional nano-structures is not more than 1000 nm.

In some exemplary embodiments or any combination of exemplary embodiments of the method of manufacturing the micro-LED panel, step 1, width of the mesa structure is not more than 3 μm.

In some exemplary embodiments or any combination of exemplary embodiments of the method of manufacturing the micro-LED panel, in step 5, material of the re-growth layer with intrinsic doped ions is the same as material of the first type semiconductor layer and/or material of the second type semiconductor layer but without intentional doping ions.

In some exemplary embodiments or any combination of exemplary embodiments of the method of manufacturing the micro-LED panel, material of the re-growth layer is monocrystal.

In some exemplary embodiments or any combination of exemplary embodiments of the method of manufacturing the micro-LED panel, material of the re-growth layer is one or more of GaP, AlP, GaAs, InP, AlInP, GaInP, AlN, GaN, and/or InN.

In some exemplary embodiments or any combination of exemplary embodiments of the method of manufacturing the micro-LED panel, in step 5, a band gap of the re-growth layer is greater than a band gap of the light emitting layer.

In some exemplary embodiments or any combination of exemplary embodiments of the method of manufacturing the micro-LED panel, in step 5, thickness of the re-growth layer is less than thickness of the light emitting layer; and, resistance of the re-growth layer is higher than resistance of the light emitting layer.

Some exemplary embodiments of the present disclosure provide a method for manufacturing a micro LED panel, comprising the following steps:
step 1, supplying a semiconductor substrate with an epitaxial structure, wherein the epitaxial structure from top down comprises: a first type epitaxial layer, a light emitting layer and a second type epitaxial layer;
step 2, forming a bottom contact on top of the epitaxial structure;
step 3, forming a mesa structure by patterning the epitaxial structure;
step 4, forming a photonic crystal structure array comprising a plurality of photonic crystal structures in the mesa structure;
step 5, forming a re-growth layer on sidewall and top of the photonic crystal structures, in space between adjacent mesa structures and covering the bottom contact;
step 6, forming a bottom connected structure on top of the bottom contact;
step 7, bonding the bottom connected structure with an IC backplane by turning the semiconductor substrate upside down; then, removing the semiconductor substrate; and
step 8, forming a top contact and a top conductive layer on top of the re-growth layer and on top of the mesa structure.

In some exemplary embodiments or any combination of exemplary embodiments of the method of manufacturing the micro-LED panel, in step 4, the photonic crystal structure is a one dimensional nano-structure.

In some exemplary embodiments or any combination of exemplary embodiments of the method of manufacturing the micro-LED panel, the one dimensional nano-structures are formed in the mesa structure along a light emitting direction of the mesa structure.

In some exemplary embodiments or any combination of exemplary embodiments of the method of manufacturing the micro-LED panel, the one dimensional nano-structures are formed perpendicular to the light emitting layer.

In some exemplary embodiments or any combination of exemplary embodiments of the method of manufacturing the micro-LED panel, diameter of the one dimensional nano-structures is not more than 1000 nm.

In some exemplary embodiments or any combination of exemplary embodiments of the method of manufacturing the micro-LED panel, step 1, width of the mesa structure is not more than 3 μm.

In some exemplary embodiments or any combination of exemplary embodiments of the method of manufacturing the micro-LED panel, in step 5, the top surface of the re-growth layer is planarized and is higher than top surface of the photonic crystal structure array and top surface of the bottom contact; and, material of the re-growth layer with intrinsic doped ions is the same as material of the first type semiconductor layer and/or material of the second type semiconductor layer but without intentional doping ions.

In some exemplary embodiments or any combination of exemplary embodiments of the method of manufacturing the micro-LED panel, material of the re-growth layer is monocrystal.

In some exemplary embodiments or any combination of exemplary embodiments of the method of manufacturing the micro-LED panel, material of the re-growth layer is one or more of GaP, AlP, GaAs, InP, AlInP, GaInP, AlN, GaN, and/or InN.

In some exemplary embodiments or any combination of exemplary embodiments of the method of manufacturing the micro-LED panel, in step 5, a band gap of the re-growth layer is greater than a band gap of the light emitting layer.

In some exemplary embodiments or any combination of exemplary embodiments of the method of manufacturing the micro-LED panel, in step 5, thickness of the re-growth layer is less than thickness of the light emitting layer, and, resistance of the re-growth layer is higher than resistance of the light emitting layer.

In some exemplary embodiments or any combination of exemplary embodiments of the method of manufacturing the micro-LED panel, in step 6, the bottom connected structure is formed in the re-growth layer on the top of the bottom contact.

The micro LED panel provided by the present disclosure can avoid the nonradiative recombination at the sidewalls of the micro LED structure. Furthermore, compared with the conventional micro LEDs, the micro LED structure of the present disclosure has a high directional emission, with no other reflective structure, thereby simplifying the micro LED structure and decreasing the cost. Furthermore, the present disclosure can also inhibit the non-radiation recombination at the surface of the micro LED structures, thereby improving the image quality and increase the EQE of the pixels.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

For convenience, “up” is used to mean away from the substrate of a light emitting structure as shown in the Figures, “down” means toward the substrate, and other directional terms such as top, bottom, above, below, under, beneath, etc. are interpreted accordingly.

FIG. 1 is a sectional diagram of a micro LED panel according to some embodiments (for example, the first embodiment) of the present disclosure.

FIGS. 2 to 11 separately illustrate the steps of a method of manufacturing the micro LED panel according to some embodiments (for example, the first embodiment).

FIG. 12 is a sectional structure diagram of a micro LED panel according to some embodiments (for example, the second embodiment) of the present disclosure.

FIGS. 13 to 21 separately illustrate the steps of a method of manufacturing the micro LED panel according to some embodiments (for example, the second embodiment).

FIG. 22 is a sectional structure diagram of a micro LED panel according to some embodiments (for example, the third embodiment) of the present disclosure.

FIGS. 23 to 32 separately illustrate the steps of a method of manufacturing the micro LED panel according to some embodiments (for example, the third embodiment).

FIG. 33 is a sectional structure diagram of another micro LED panel according to some embodiments (for example, the fourth embodiment) of the present disclosure.

FIG. 34 is a top view of the mesa structure in FIG. 33 according to some embodiments (for example, the fourth embodiment) of the present disclosure.

FIGS. 35 to 42 separately illustrate the steps of a method of manufacturing the micro LED panel according to some embodiments (for example, the fourth embodiment).

FIG. 43 illustrates another step 6 of depositing a dielectric layer according to some embodiments (for example, the fourth embodiment).

FIG. 44 is a sectional structure diagram of another micro LED panel according to some embodiments (for example, the fourth embodiment) of the present disclosure.

FIG. 45 is a sectional structure diagram of a micro LED panel according to some embodiments (for example, the fifth embodiment) of the present disclosure.

FIGS. 46 to 54 separately illustrate the steps of a method of manufacturing the micro LED panel according to some embodiments (for example, the fifth embodiment).

FIG. 55 is a sectional structure diagram of a micro LED panel according to some embodiments (for example, the sixth embodiment) of the present disclosure.

FIGS. 56 to 59 separately illustrate from step 5 to step 8 of a method of manufacturing the micro LED panel according to some embodiments (for example, the sixth embodiment).

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

As discussed above, to resolve the problem in the related technologies, in some embodiments, a micro LED panel comprising multiple micro LED structures is disclosed in the present disclosure. The dimension of the micro LED panel is not more than 1 cm. The micro LED structures are formed in the micro LED panel in an array, with a resolution such as 720*480, 640*480, 1920*1080, 1280*720, 2k, or 4k. The diameter of the micro LED structure is at a nano-meter level, such as 20 nm to 100 nm.

FIG. 1 is a sectional diagram of a micro LED panel according to some embodiments (for example, the first embodiment) of the present disclosure.

Referring to FIG. 1, the micro LED structure comprises a mesa structure. The mesa structure is formed by a first type epitaxial layer 01, a light emitting layer 03 and a second type epitaxial layer 02 from bottom to top. The first type and the second type are different conductive types, for example, the first type is P type, while the second type is N type. In another example, the first type is N type, while the second type is P type. In some embodiments, the material of the first type epitaxial layer 01 can be one or more of GaAs, InGaAs, GaP, GaN, InGaN, AlGaN, AlInP, GaInP, AlGaInP, AlP, InP, AlN, and/or InN, etc., or any combinations thereof, preferably one or more of GaAs, InGaAs, GaP, GaN, InGaN, AlGaN, AlInP, GaInP, and/or AlGaInP, or any combinations thereof, and the material of the second type epitaxial layer 02 can be one or more of GaAs, InGaAs, GaP, GaN, InGaN, AlGaN, AlInP, GaInP, AlGaInP, AlP, InP, AlN, and/or InN, etc., or any combinations thereof, preferably one or more of GaAs, InGaAs, GaP, GaN, InGaN, AlGaN, AlInP, GaInP, and/or AlGaInP, or any combinations thereof.

In some embodiments, the light emitting layer 03 is formed by multiple stacked pairs of quantum well layers. The material of the quantum well layer can be one of GaAs, InGaAs, GaP, GaN, InGaN, AlGaN, AlInP, GaInP, AlGaInP, etc. Additionally, the thickness of the first type epitaxial layer 01 is larger than the thickness of the second type epitaxial layer 02 and the thickness of the light emitting layer 03 is less than that of the first type epitaxial layer 01. Preferably, the thickness of the first type epitaxial layer 101 is 700 nm to 2 μm, the thickness of the second type epitaxial layer 02 is 100 to 200 nm. Preferably, the thickness of a single quantum well layer is not more than 30 nm. In some examples, the light emitting layer 03 includes not more than three pairs of quantum well layers. Additionally, the light emitting layer 03 has a straight line shape without any bending.

In some embodiments, the first type epitaxial layer 01 may have multiple stacked first type semiconductor sub-layers, the second type epitaxial layer 02 may have multiple stacked second type semiconductor sub-layers. For example, the top layer of the first type epitaxial sub-layer is a P cap layer connected with the bottom of the light emitting layer, the bottom layer of the second type epitaxial sub-layer is a N cap layer connected with the top of the light emitting layer 03, for protecting the quantum well layers from being damaged.

Furthermore, the first type epitaxial layer 01 comprises one or more reflective mirror layers 011 (not shown in FIG. 1) thereof. The reflective mirror layer(s) 011 can be formed at the bottom surface of the first type epitaxial layer 01 or formed in the inner of the first type epitaxial layer 01. The material of the reflective mirror layer is a combination of a dielectric material and a metal material. In some embodiments, multiple reflective mirror layers 011 are horizontally formed in the first type epitaxial layer 01 one by one in different horizontal levels, thereby dividing the first type epitaxial layer 01 into multiple layers. Additionally, the material of the first epitaxial layer is monocrystal and the material of the second epitaxial layer is monocrystal.

Referring to FIG. 1, the top contact 09 and the top conductive layer 08 is formed at the top surface of the second type epitaxial layer 02. The conductive type of the top contact 09 is the same as that of the second type epitaxial layer 02, such as, the second type is n type, and the top contact 09 is n type top contact, or, the second type is p type, and the top contact 09 is p type top contact. In some embodiments, the top contact 09 is made by metal or metal alloy, such as, AuGe, AuGeNi, etc. The top contact 09 is used for forming ohmic contact between the top conductive layer 08 and the second type epitaxial layer 02, so as to optimize the electrical property of the micro LEDs. The diameter of the top contact 09 is about 20 nm to 50 nm and the thickness of the top contact 09 is about 10 nm to 20 nm. In some embodiments, the top conductive layer 08 is transparent and electrically conductive, such as Indium Tin Oxide (ITO), Fluorine-doped Tin Oxide (FTO), etc.

In the present disclosure, to realize high directional light emission of the micro LED structure, a photonic crystal structure array is formed in the mesa structure. In some embodiments, the photonic crystal structure array is formed through the light emitting layer 03. Furthermore, the photonic crystal structure array is formed on the emitting surface of the mesa structure. Preferably, the photonic crystal structure array is formed through the mesa structure from top to bottom.

Additionally, in some embodiments, the top conducive layer 08 is continuously formed on the whole micro LED panel. Herein, “whole” means a substantial portion or all. In another embodiment, referring to FIG. 11, the top conductive layer 08 is not connected with each other between the adjacent mesa structures.

Hereinafter, the detail of the micro LED panel will be further described in consistent with the figures.

### The First Embodiment

To resolve the problem in the related technologies, a micro LED panel is provided in the embodiments of the present disclosure.

The micro LED panel comprises a micro LED array. Referring to FIG. 1, the micro LED structure in the micro LED array at least comprises: a mesa structure comprising 01, 02 and 03 and a photonic crystal structure array. The mesa structure from bottom to top comprises a first type epitaxial layer 01, a light emitting layer 03 and a second type epitaxial layer 02. The photonic crystal structure array is formed through the mesa structure. A gap is between the adjacent photonic crystal structures 10. Herein, the top of the photonic crystal structures are the top of the mesa structure and the bottom of the photonic crystal structures are the bottom of the mesa structure. Additionally, to achieve high image quality, the width of the mesa structure is not more than 3 μm.

Additionally, the photonic crystal structure 10 is one dimensional nano-structure. Multiple of the one dimensional nano-structures are distributed in an array. The one dimensional nano-structures are formed in the mesa structure along the light emitting direction. Furthermore, the one dimensional nano-structures are formed perpendicular to the light emitting layer 03. The one dimensional nano-structure is like a nanowire, nanorod, nanofiber, etc. Preferably, the diameter of the one dimensional nano-structures is not more than 1000 nm.

Referring to FIG. 1, a dielectric layer 05 is filled in the gap between the adjacent photonic crystal structures. Furthermore, the dielectric layer 05 can be further formed on the sidewall of the mesa structure. Preferably, the material of the dielectric layer 05 is selected from one or more of SiO₂, SiNx, Al₂O₃, AlN, HfO₂, TiO₂, and/or ZrO₂, etc. The dielectric layer 05 in the gap between the adjacent photonic crystal structures is transparent and electrically isolated. Additionally, the dielectric layer 05 is further formed in the space between the adjacent mesa structures, even fully filled in the space between the adjacent mesa structures.

A top contact 09 is formed on the top of the mesa structure and a top conductive layer 08 is formed on the top contact 09 and the top of the mesa structure. Herein, the top conductive layer 08 is continuously formed on the whole micro LED structure array. Additionally, when the top of the dielectric layer 05 is lower than the top of the photonic crystal structures, the top conductive layer 08 is filled in some of the gap between the adjacent photonic crystal structures; and, the bottom of the top contact 09 is filled in some of the gap between the adjacent photonic crystal structures. Herein, the light emitting direction is from bottom to top, so the top conductive layer 08 is transparent.

In some embodiments, the bottom contact layer 06′ is formed at the bottom surface of the first type epitaxial layer 01. The conductive type of the bottom contact is the same as that of the first type epitaxial layer 01, such as, the first type epitaxial layer 01 is P type, the bottom contact layer 06′ is also P type. Furthermore, since the light emits upward or downward from the LED mesa structure consisting or comprising of the first type epitaxial layer 01, the second type epitaxial layer 02 and the light emitting layer 03, the diameter of the bottom contact layer 06′ is larger than the diameter of the top contact 09. While the diameter of the top contact 09 can be as small as possible, the top contact 09 can also be as small as a dot on the top surface of the second type epitaxial layer 02. For example, the width of the top contact 09 is less than ⅕, ⅙, 1/10 or 1/20 of the width of the second-type epitaxial layer 02 or the mesa structure. In another embodiment, the diameter of the bottom contact layer 06′ can also be equal to or smaller than the diameter of the top contact 09. A bottom connected layer 07′ is formed at the bottom of the bottom contact layer 06′. The bottom connected layer 07′ is used for connecting with the bottom electrode such as the contact pad in an IC backplane 00. Furthermore, the diameter of the bottom connected structure 07 is 20 nm to 1 μm. Preferably, the diameter of the bottom connected layer 07′ is 800 nm to 1 μm. Furthermore, the center of the bottom contact layer 06′ is aligned with the center of the top contact 09 in the vertical direction. Additionally, the material of the bottom contact layer 06′ and the bottom connected layer 07′ are transparent conductive material, such as ITO, or FTO, etc. Additionally, the material of the bottom contact layer 06′ and the bottom connected layer 07′ are not transparent. The material of the bottom contact layer 06′ and the bottom connected layer 07′ can be conductive metal. Preferably, the material of the bottom contact layer 06′ can be selected from at least one of Au, Zn, Be, Cr, Ni, Ti, Ag and Pt. The material of the bottom connected layer 07′ can be selected from at least one of Au, Zn, Be, Cr, Ni, Ti, Ag and Pt.

In some embodiments, herein the center of the bottom contact layer 06′ is vertically aligned with the center of the first type epitaxial layer 01. But, in another embodiment, the center of the bottom contact layer 06′ is not vertically aligned with the center of the first type epitaxial layer 01.

In some embodiments, the method of manufacturing the aforementioned micro LED panel in this first embodiment comprises the following steps:

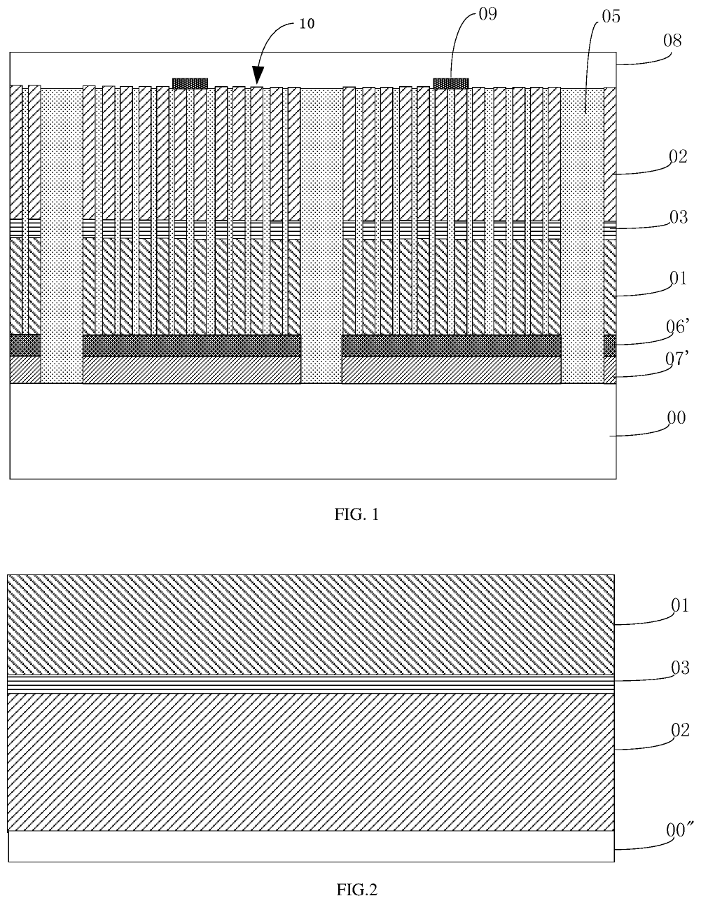

FIGS. 2 to 11 separately illustrates the steps of a method of manufacturing the micro LED panel according to some embodiments (for example, the first embodiment).

Referring to FIG. 2, step 1 includes supplying a semiconductor substrate 00″ with an epitaxial structure.

Herein, the epitaxial structure comprises a first type epitaxial layer 01, a light emitting layer 03 and a second type epitaxial layer 02 from top to bottom. The material of the semiconductor substrate 00″ can be GaN, GaAs, etc. The epitaxial structure is grown on the substrate 00″.

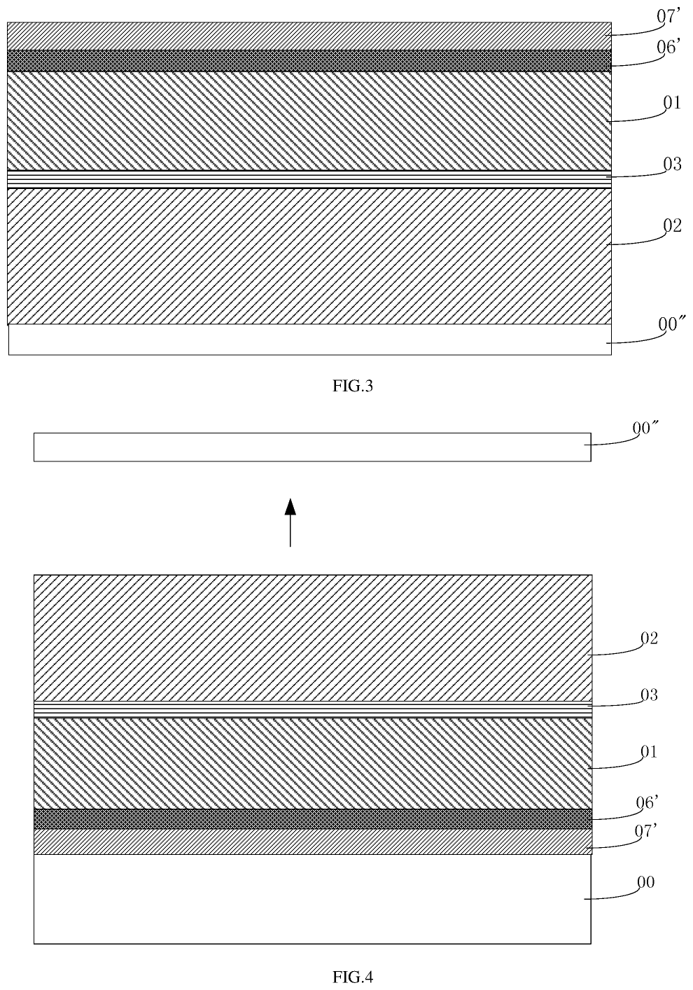

Referring to FIG. 3, step 2 includes forming a bottom contact layer 06′ and a bottom connected layer 07′ in order on the top surface of the first type epitaxial layer 01.

Herein, the bottom contact layer 06′ and the bottom connected layer 07′ are deposited in order by a conventional physical vapor deposition method. The bottom connected layer 07′ is also as a metal bonding layer for a subsequent metal bonding process in step 3.

Referring to FIG. 4, step 3 includes bonding the bottom connected layer 07′ with an IC backplane 00 by turning the semiconductor substrate 00″ upside down. Then, removing the semiconductor substrate 00″.

Herein, the semiconductor substrate 00″ with the epitaxial structure is firstly turned upside down. Then, the bottom connected layer 07′ is bonded with pads of the IC backplane 00. After the bonding process, the semiconductor substrate 00″ is removed by a conventional removing process, such as a laser lift-off method.

Referring to FIG. 5, step 4 includes forming a photonic crystal structure array by etching the epitaxial structure.

Herein, the second type epitaxial layer 02, the light emitting layer 03 and the first type epitaxial layer 01 are etched in order from top down and stopped on the top of the bottom contact layer 06′ by a plasma etching process, so the photonic crystal structure array is formed through the whole mesa structure from top to bottom. Preferably, the power for etching is 200 W˜800 W, the time for etching is 50 S˜300 S.

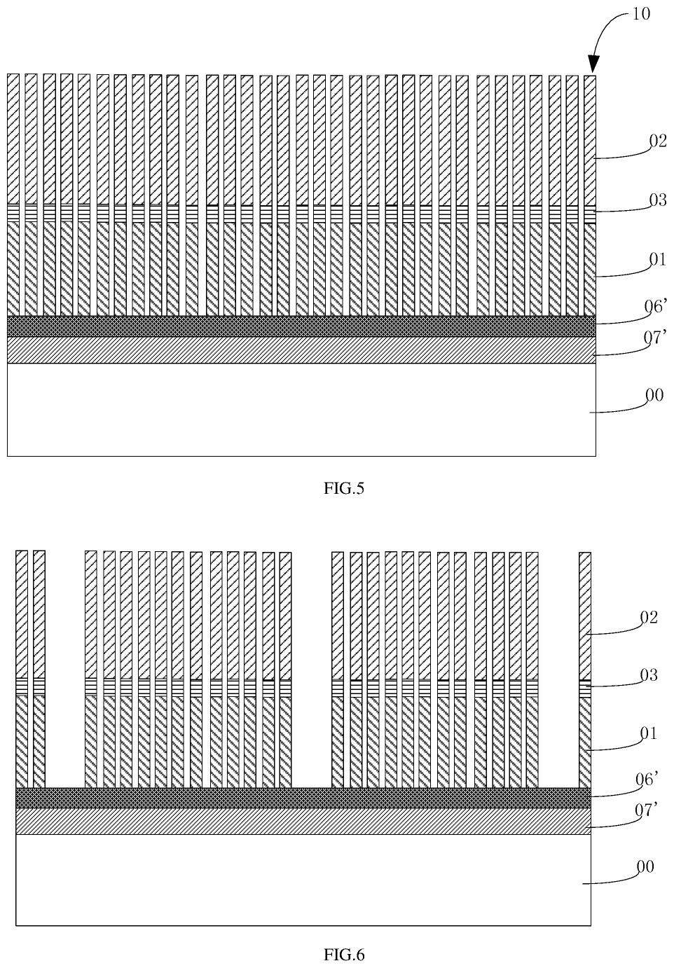

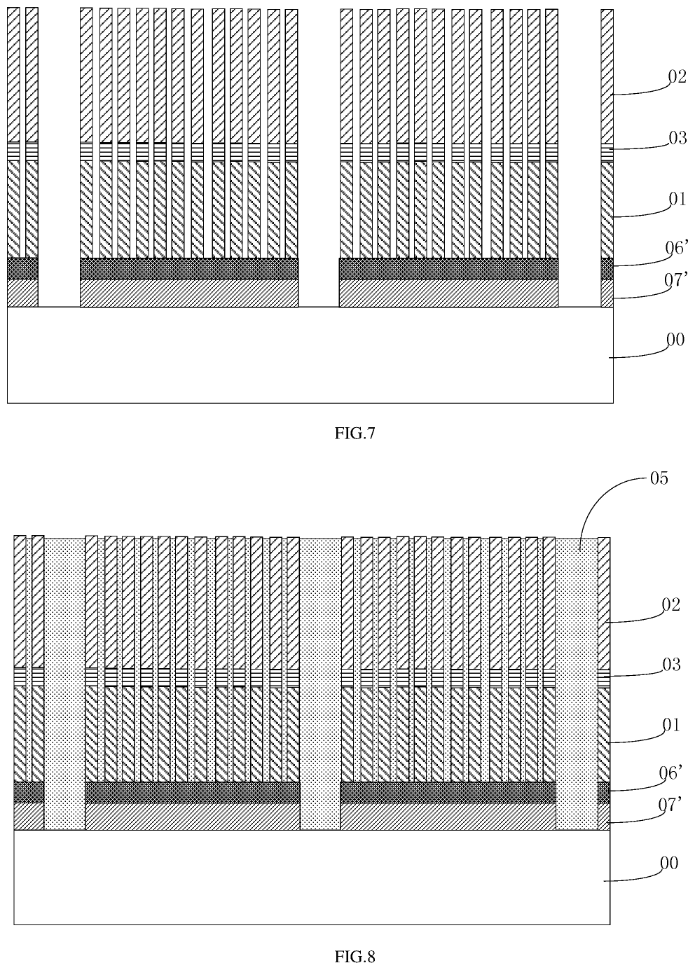

Referring to FIGS. 6 and 7, step 5 includes forming a space to define a mesa structure by etching the photonic crystal structure array, the bottom contact layer 06′ and the bottom connected layer 07′ from top to bottom.

Herein, referring to FIG. 6, the photonic crystal structure array is further etched by a conventional plasma etching process to define a mesa structure; a space is formed between the adjacent mesa structures. Referring to FIG. 7, the bottom contact layer 06′ and the bottom connected layer 07′ are further etched from top to bottom, so that the bottom of the space extends to the top of the IC backplane 00. Therefore, the bottom connected layer 06′ and the bottom contact layer 07′ are isolated by the space.

Referring to FIG. 8, step 6 includes forming a dielectric layer 05 on the sidewall of the photonic crystal structures.

Herein, the dielectric layer 05 is deposited on the sidewall of the photonic crystal structures by a conventional chemical vapor deposition method. The dielectric layer 05 is further fully filled in the gap between the adjacent photonic crystal structures. Furthermore, the dielectric layer 05 is formed in the space between the adjacent mesa structures. Preferably, the dielectric layer 05 is fully filled in the space between the adjacent mesa structures. In another embodiment, the dielectric layer 05 is only formed on the sidewall of the mesa structures and not fully filled in the space between the adjacent mesa structures.

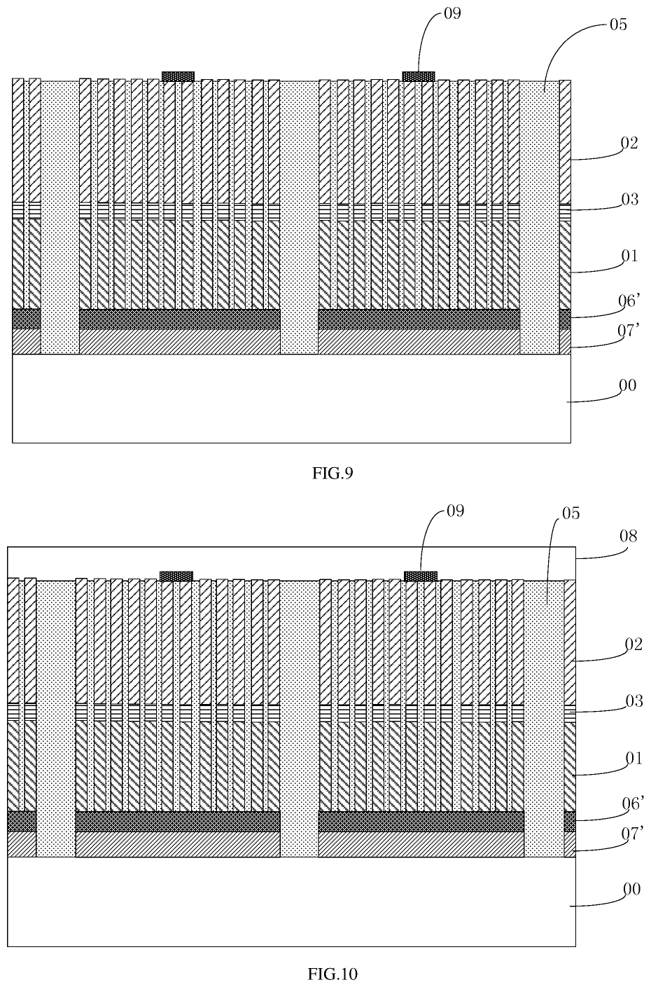

Referring to FIGS. 9 and 10, step 7 includes forming a top contact 09 and a top conductive layer 08 on the top of the dielectric layer 05 and the top of the mesa structure.

Herein, referring to FIG. 9, the top contact 09 is deposited on the top of the second type epitaxial layer 02 with a mask protecting the other region, and then the mask is removed. Then, referring to FIG. 10, a top conductive layer 08 is deposited on the second epitaxial layer 02 by a conventional vapor deposition process. Herein, the top conductive layer 08 is formed on the top of the photonic crystal structures, on the top of the dielectric layer 05 and covers the top contact 09. In another embodiment, the dielectric layer 05 is only formed on the sidewall of the mesa structures and not fully filled in the space, so the top conductive layer 08 is further formed in the space between the adjacent mesa structures.

In another embodiment, referring to FIG. 11, the top conductive layer 08 is not connected with each other between the adjacent mesa structures.

### The Second Embodiment

To resolve the problem in the related technologies, a micro LED panel is provided in the embodiments of the present disclosure.

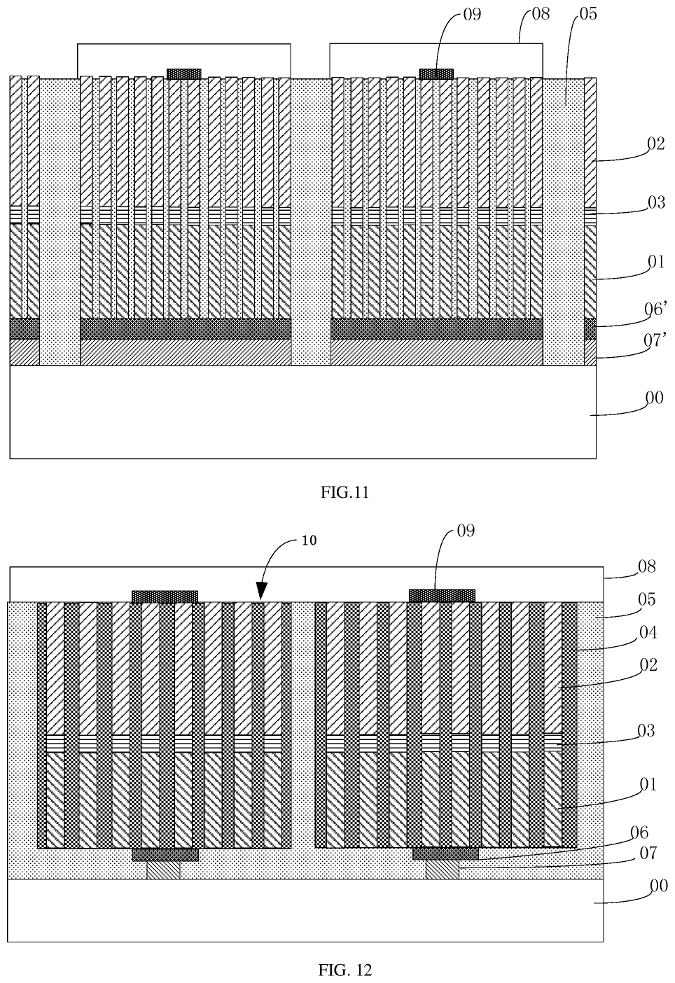

The micro LED panel comprises a micro LED array. FIG. 12 is a sectional structure diagram of a micro LED panel according to some embodiments (for example, the second embodiment) of the present disclosure.

Referring to FIG. 12, the micro LED structure in the micro LED array at least comprises: a mesa structure and a photonic crystal structure array. The mesa structure from bottom to top comprises a first type epitaxial layer 01, a light emitting layer 03 and a second type epitaxial layer 02. The photonic crystal structure array is formed through the mesa structure. A gap is between the adjacent photonic crystal structures 10. Herein, the top of the photonic crystal structures are the top of the mesa structure and the bottom of the photonic crystal structures are the bottom of the mesa structure. Additionally, to achieve high image quality, the width of the mesa structure is not more than 3 μm.

In some embodiments, the photonic crystal structure 10 is one dimensional nano-structure. Multiple of the one dimensional nano-structures are distributed in an array. The one dimensional nano-structures are formed in the mesa structure along the light emitting direction. Furthermore, the one dimensional nano-structures are formed perpendicular to the light emitting layer 03. The one dimensional nano-structure is like a nanowire, nanorod, nanofiber, etc. Preferably, the diameter of the one dimensional nano-structures is not more than 1000 nm.

A re-growth layer 04 is formed at least part of the sidewall of the mesa structure. Herein, the re-growth layer is formed on the sidewall of the whole mesa structure. In another embodiment, the re-growth layer is formed at least part of the sidewall of the first type epitaxial layer, the whole sidewall of the light emitting layer and at least part of the sidewall of the first type epitaxial layer. In some embodiments, the re-growth layer can be formed on at least part of the sidewall of the first type epitaxial layer and the whole sidewall of the light emitting layer; or, the re-growth layer can be formed on at least part of the sidewall of the second type epitaxial layer and the whole sidewall of the light emitting layer; or, the re-growth layer can be formed on at least part of the sidewall of the light emitting layer.

Referring to FIG. 12 again, the re-growth layer 04 is further formed at the sidewall of the photonic crystal structures. Preferably, the re-growth layer is fully filled in the gap between the adjacent photonic crystal structures.

Furthermore, the re-growth layer 04 which is formed on the sidewall of the light emitting layer 03 is not parallel to the extending direction of the light emitting layer 03. Furthermore, the light emitting layer 03 comprises a top surface, an edge surface and a bottom surface; and, the re-growth layer 04 is only grown on the edge surface of the light emitting layer 03 but not grown on the top surface and the bottom surface of the light emitting layer 03. Preferably, the inclined angle of the re-growth layer 04 on the sidewall of the light emitting layer is 30 degrees to 90 degrees relative to the horizontal extending direction of light emitting layer 03. That is to say, the re-growth layer 04 is grown on the end surface of the light emitting layer 03, not grown on the top and bottom of the light emitting layer 03. Additionally, the light emitting layer 03 comprises a plurality of pairs of quantum wells. The re-growth layer 04 is not parallel to the surface of each of the plurality of pairs of quantum wells. Herein, the light emitting layer 03 has a straight line shape without any bending. Preferably, the diameter of the mesa structure is not more than 3 μm. Furthermore, the bottom of the photonic crystal structure array is aligned with the bottom of the mesa structures, and the top of the photonic crystal structure array is aligned with the top of the re-growth layer 04.

Herein, the material of the re-growth layer 04 with intrinsic doped ions is the same as the material of the first type epitaxial layer 01 and/or the material of the second type epitaxial layer 02 but without intentional extrinsic doping ions. For example, when the materials of first type epitaxial layer 01 and the second type epitaxial layer 02 are the same, and the intentional ion doping levels for the material of first type epitaxial layer 01 and the material of the second type epitaxial layer 02 are different, the material of the re-growth layer 04 may be the same as the underlying first type epitaxial layer 01 and the material of the second type epitaxial layer 02 but without the intentional extrinsic doping ions. In another example, when the material of first type epitaxial layer 01 and the second type epitaxial layer 02 are not the same, and the intentional ion doping levels for the material of first type epitaxial layer 01 and the material of the second type epitaxial layer 02 are different, the material of the re-growth layer 04 may be the same as the first type epitaxial layer 01 or the material of the second type epitaxial layer 02 but without the intentional extrinsic doping ions. The light emitting layer is an active region of a PN-junction formed by the first type epitaxial layer 01 and the second type epitaxial layer 02, and can be considered as composed of the two materials of the first type epitaxial layer 01 and the second type epitaxial layer 02. In some embodiments, the portion of the material of the re-growth layer that covers the first type epitaxial layer 01 is the same as the underlying first type epitaxial layer 01 but without the extrinsic intentional doping of the first type epitaxial layer 01, and the portion of the material of the re-growth layer that covers the second type epitaxial layer 02 is the same as the underlying second type epitaxial layer 02 but without the extrinsic intentional doping of the second type epitaxial layer 02. In some embodiments, the re-growth layer 04 can have some intrinsic doping levels or without doping levels. In some embodiments, the material growth parameters, such as the ambient/gas pressure, the power, and the material for the re-growth process are the same or similar as that of the first type epitaxial layer 01 and/or second type epitaxial layer 02. The material of the re-growth layer 04 must be lattice matched with the light emitting layer 03, the first type epitaxial layer 01 and/or the second type epitaxial layer 02. Preferably, the material of the re-growth layer 04 is monocrystal, the material of the first epitaxial layer 01 is monocrystal and the material of the second epitaxial layer 02 is monocrystal. Furthermore, the material of the re-growth layer 04 is one or more of GaAs, InGaAs, GaP, GaN, InGaN, AlGaN, AlInP, GaInP, AlGaInP, AlP, InP, AlN, and/or InN, etc., or any combinations thereof, preferably one or more of GaP, AlP, GaAs, InP, AlInP, GaInP, AlN, GaN, and/or InN, or any combinations thereof. In another embodiment, the material of the re-growth layer 04 is without intentional doping ions and is not the same as the material of the first type epitaxial layer or the material of the second type epitaxial layer 02.

The resistance of the re-growth layer 04 is higher than the resistance of the light emitting layer 03 and the re-growth layer 04 is not electrically conductive, thereby ensuring the normal work of the micro LED structures, and stopping the carries from spreading outside the light emitting layer 03. Preferably, the band gap of the re-growth layer 04 is greater than the band gap of the light emitting layer 03. Furthermore, the thickness of the re-growth layer 04 is less than the thickness of the light emitting layer 03, preferably, the thickness of the re-growth layer 04 is not more than 100 nm or 10 nm. In another embodiments, the thickness of the re-growth layer 04 is equal to or more than the thickness of the light-emitting layer 03.

Referring to FIG. 12, a dielectric layer 05 is further formed in the space between the adjacent mesa structures. Preferably, the dielectric layer 05 is fully filled in the space between the adjacent mesa structures. The dielectric layer 05 is preferably transparent and electrically isolated. Preferably, the material of the dielectric layer 05 is selected from one or more of SiO₂, SiNx, Al₂O₃, AlN, HfO₂, TiO₂, and/or ZrO₂, etc.

A top contact 09 is formed on the top of the mesa structure and a top conductive layer 08 is formed on the top contact 09 and the top of the mesa structure. Herein, the top conductive layer 08 is continuously formed on the whole micro LED structure array. Additionally, when the top of the dielectric layer 05 is lower than the top of the photonic crystal structures, the top conductive layer 08 is filled in some of the gap between the adjacent photonic crystal structures; and, the bottom of the top contact 09 is filled in some of the gap between the adjacent photonic crystal structures. Herein, the light emitting direction is from bottom to top, so the top conductive layer 08 is transparent.

A bottom contact 06 is formed at the bottom surface of the first type epitaxial layer 02. The conductive type of the bottom contact is the same as that of the first type epitaxial layer 01, such as, the first type epitaxial layer 01 is P type, the bottom contact 06 is also P type. Furthermore, since the light emits upward or downward from the mesa structure, the diameter of the bottom contact 06 is larger than the diameter of the top contact 09. While the diameter of the top contact 09 can be as small as possible, the top contact 09 can also be as small as a dot on the top surface of the second type epitaxial layer 02. In another embodiment, the diameter of the bottom contact 06 can also be equal to or smaller than the diameter of the top contact 09. A bottom connected structure 07 is formed at the bottom of the bottom contact 06. The bottom connected structure 07 is used for connecting with the bottom electrode such as the contact pad in an IC backplane 00. Furthermore, the diameter of the bottom connected structure 07 is 20 nm to 1 μm. Preferably, the diameter of the bottom connected structure 07 is 800 nm to 1 μm. Furthermore, the center of the bottom contact 06 is aligned with the center of the top contact 09 in the vertical direction. Additionally, the material of the bottom contact 06 and the bottom connected structure 07 are transparent conductive material, such as ITO, or FTO, etc. Additionally, the material of the bottom contact 06 and the bottom connected structure 07 are not transparent. The material of the bottom contact 06 and the bottom connected structure 07 can be conductive metal. Preferably, the material of the bottom contact 06 can be selected from at least one of Au, Zn, Be, Cr, Ni, Ti, Ag and Pt. The material of the bottom connected structure 07 can be selected from at least one of Au, Zn, Be, Cr, Ni, Ti, Ag and Pt.

In some embodiments, the center of the bottom contact 06 is vertically aligned with the center of the first type epitaxial layer 01. But, in another embodiment, the center of the bottom contact 06 is not vertically aligned with the center of the first type epitaxial layer 01. In some embodiments, the bottom contact 06 and/or the bottom connected structure 07 have the same width as the first type epitaxial layer 01 or the mesa structure.

The method of manufacturing the aforementioned micro LED panel in this second embodiment comprises the following steps.

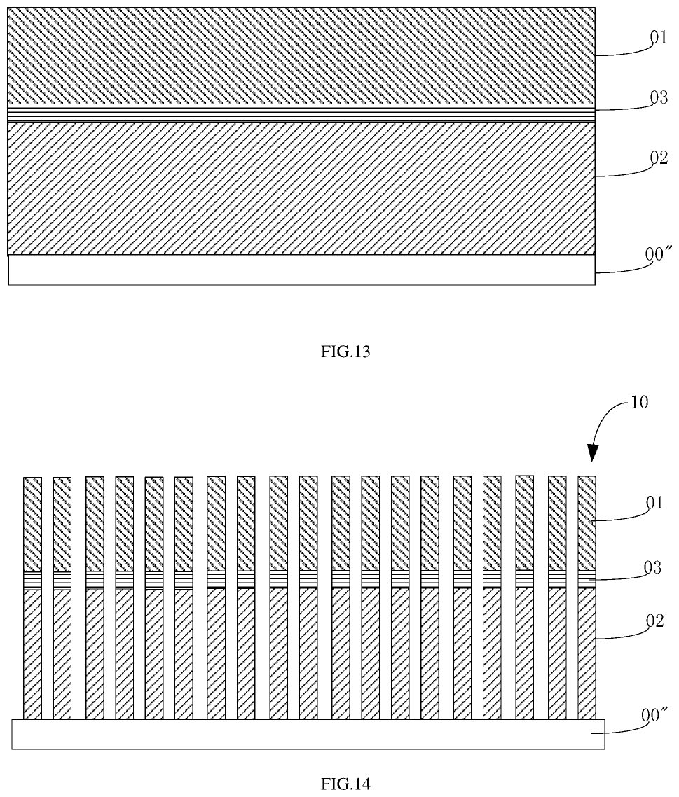

FIGS. 13 to 21 separately illustrate the steps of a method of manufacturing the micro LED panel according to some embodiments (for example, the second embodiment).

Referring to FIG. 13, step 1 includes supplying a semiconductor substrate 00″ with an epitaxial structure.

Herein, the epitaxial structure comprises a first type epitaxial layer 01, a light emitting layer 03 and a second type epitaxial layer 02 from top to bottom. The material of the semiconductor substrate 00″ can be GaN, GaAs, etc. The epitaxial structure is grown on substrate 00″.

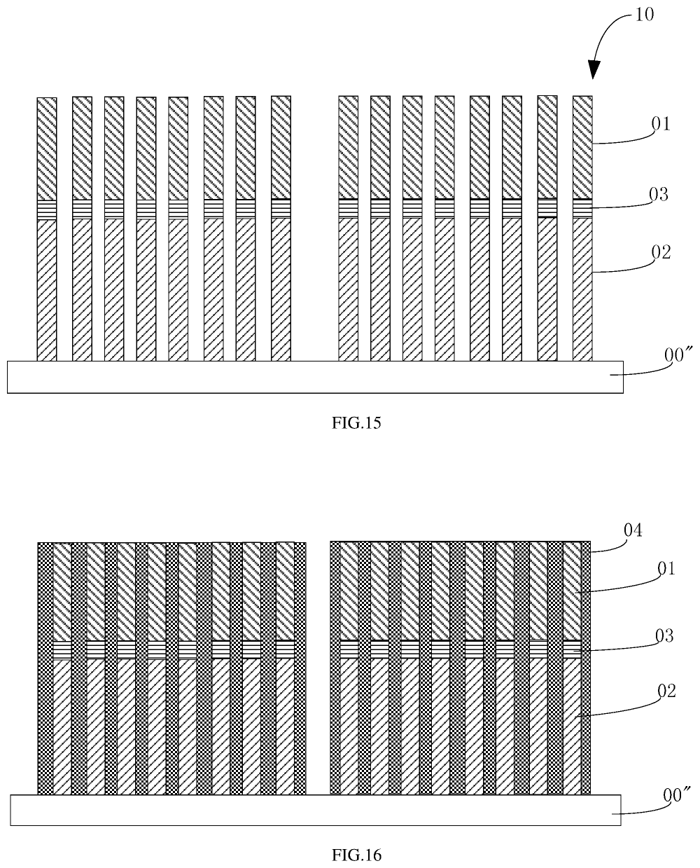

Referring to FIG. 14, step 2 includes forming a photonic crystal structure array in the epitaxial structure by etching the epitaxial structure.

Herein, the first type epitaxial layer 01, the light emitting layer 03 and the second type epitaxial layer 02 are etched in order from top down and stopped on the top of the semiconductor substrate 00″ by a plasma etching process, so the photonic crystal structure array 10 is formed through the whole mesa structure from top to bottom. Preferably, the power for etching is 200 W˜800 W, the time for etching is 50 S˜300 S.

Referring to FIG. 15, step 3 includes forming a space to define a mesa structure by etching the photonic crystal structures.

Herein, the photonic crystal structure array is further etched by a conventional plasma etching process to define a mesa structure. In some embodiments, a space is formed between the adjacent mesa structures.

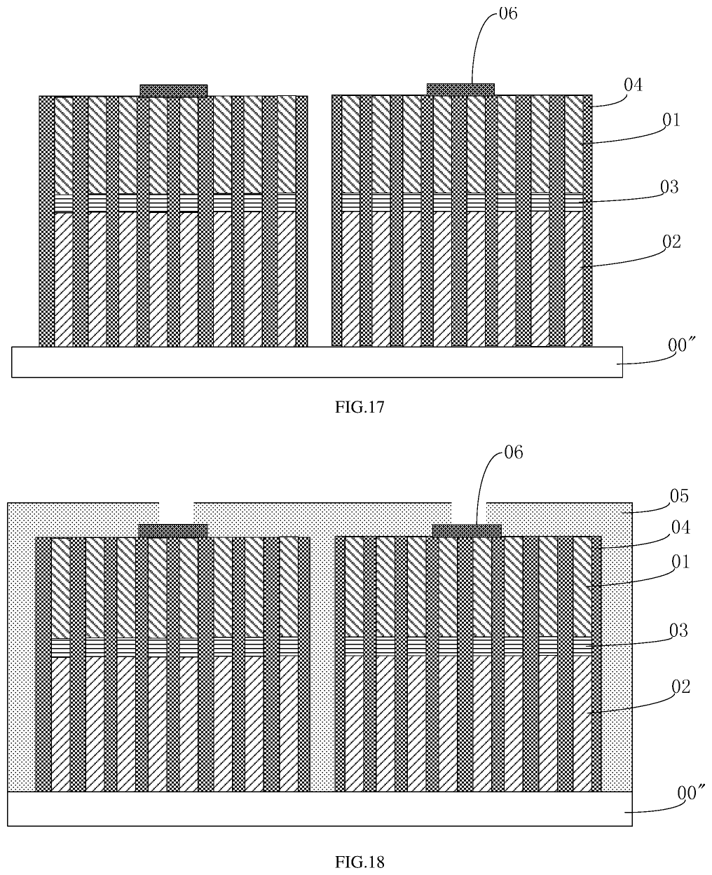

Referring to FIG. 16, step 4 includes forming a re-growth layer 04 on the sidewall of the photonic crystal structures.

Herein, in this re-growth process, the temperature is 400° C. to 1000° C., the re-growth time is 5 seconds to 1000 seconds. Herein, the material for re-growth process is preferably the same as the material of the first type epitaxial layer and/or the material of the second type epitaxial layer but without intentional doping ions. The re-growth layer is firstly grown on the sidewall of each of the photonic crystal structures and the top of the photonic crystal structures. Then, the re-growth layer on the top of the photonic crystal structures is removed by a conventional chemical mechanical polishing method. In some embodiments, herein, the re-growth layer is fully filled in the gap between the adjacent photonic crystal structures, but not fully filled in the space between the adjacent mesa structures.

Referring to FIG. 17, step 5 includes forming a bottom contact on the top of the photonic crystal structure array.

Herein, the bottom contact 06 is deposited on the top of the crystal structures array and on the top of the re-growth layer by a conventional physical vapor deposition method with a photoresist mask protecting the other region, and then the mask is removed by a conventional wet etching method.

Referring to FIG. 18, step 6 includes forming a dielectric layer 05 on the top of the photonic crystal structure array and on the top of the re-growth layer 04, and covering the bottom contact 06.

Herein, the dielectric layer 05 is firstly deposited on the top of the re-growth layer 04, on the top of the photonic crystal structure array and covers the bottom contact 06 by a conventional chemical vapor deposition method.

Then, an opening is formed in the dielectric layer 05 by a conventional plasma etching method to expose the bottom contact 06.

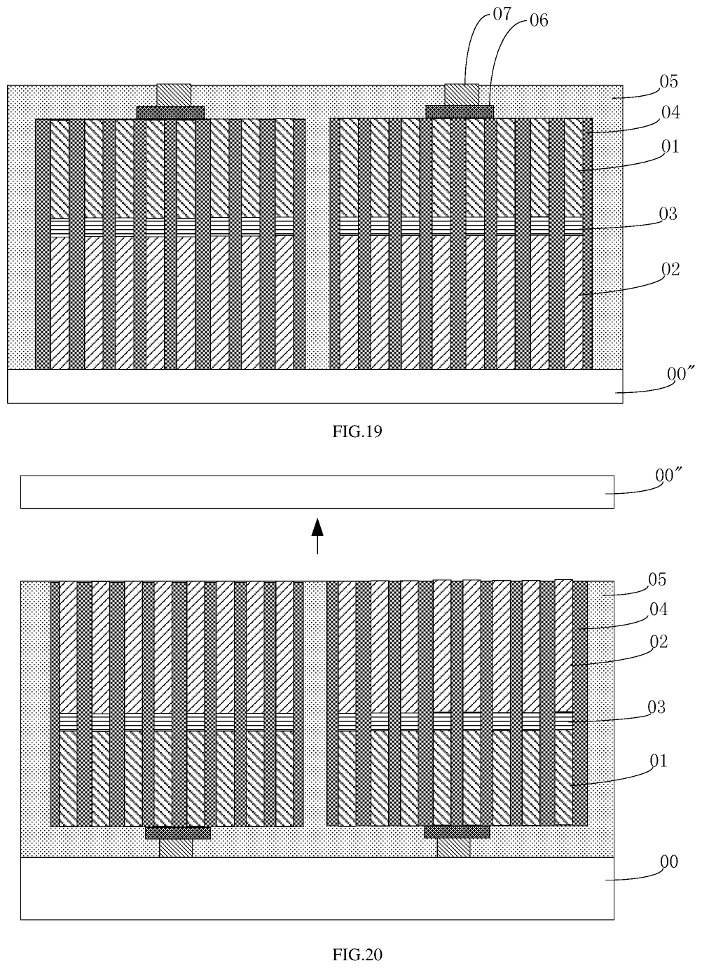

Referring to FIG. 19, step 7 includes forming a bottom connected structure 07 on the top of the bottom contact 06.

Herein, the conductive material is deposited into the opening to form a bottom connected pillar by a physical vapor process. The conductive materials can be conventional metals in the embodiment.

Referring to FIG. 20, step 8 includes bonding the bottom connected structure with an IC backplane by turning the semiconductor substrate upside down. Then, removing the semiconductor substrate.

Herein, the semiconductor substrate 00″ with the epitaxial structure is firstly turned upside down. Then, the bottom connected structure 07 is bonded with a pad of the IC backplane 00. After the bonding process, the semiconductor substrate 00″ is removed by a conventional removing process, such as a laser lift-off method.

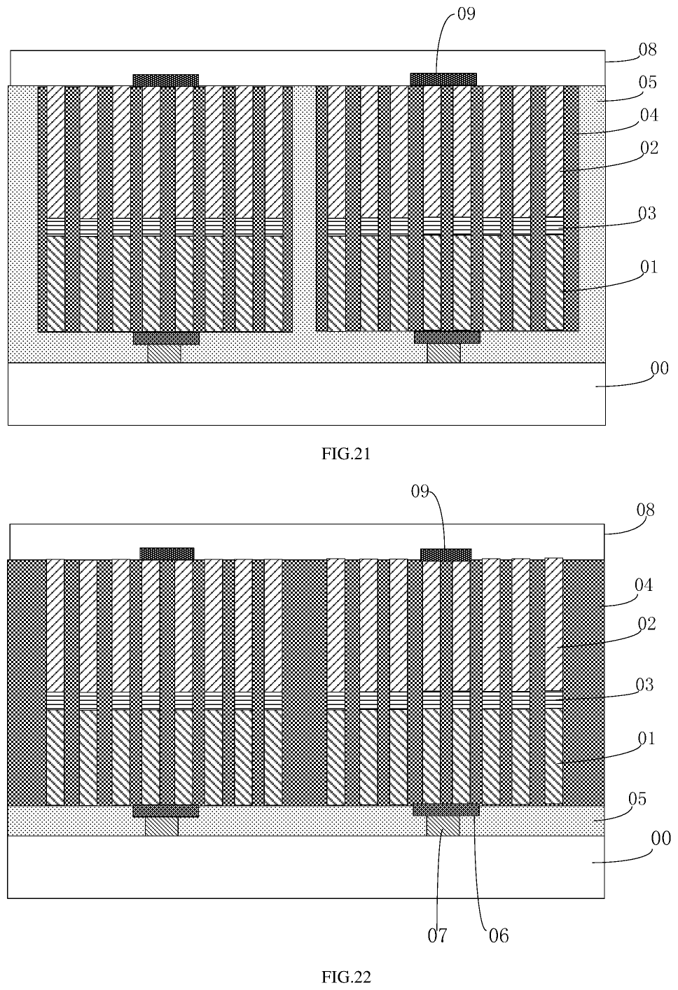

Referring to FIG. 21, step 9 includes forming a top contact 09 and a top conductive layer 08 on the top of the dielectric layer 05 and the top of the mesa structure.

Herein, the top contact 09 is deposited on the top of the second type epitaxial layer 02 with a mask protecting the other region, and then the mask is removed. Then, a top conductive layer 08 is deposited on the second epitaxial layer 02 by a conventional vapor deposition process. Herein, the top conductive layer 08 is formed on the top of the photonic crystal structures, on the top of the dielectric layer 05 and covers the top contact 09. In another embodiment, the dielectric layer 05 is only formed on the sidewall of the mesa structures and not fully filled in the space between the adjacent mesa structures, so the top conductive layer 08 is further formed in the space between the adjacent mesa structures.

### The Third Embodiment

The micro LED panel of the third embodiment comprises a micro LED structure array. FIG. 22 is a sectional structure diagram of a micro LED panel according to some embodiments (for example, the third embodiment) of the present disclosure.

Referring to FIG. 22, the difference of the third embodiment from the second embodiment is as follows: the re-growth layer 04 is fully filled in the space between the adjacent mesa structures. In some embodiments, the bottom contact 06 and/or the bottom connected structure 07 have the same width as the first type epitaxial layer 01 or the mesa structure. Other details of the micro LED panel can be referred to the second embodiment, which will not be repeated herein.

The method of manufacturing the aforementioned micro LED panel in this third embodiment comprises the following steps.

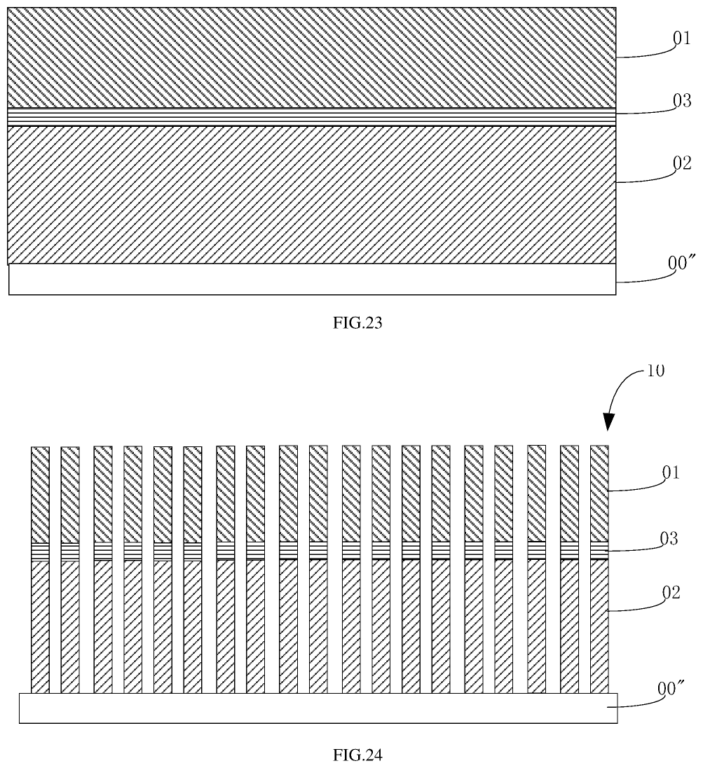

FIGS. 23 to 32 separately illustrate the steps of a method of manufacturing the micro LED panel according to some embodiments (for example, the third embodiment).

Referring to FIG. 23, step 1 includes supplying a semiconductor substrate 00″ with an epitaxial structure.

Herein, the epitaxial structure comprises a first type epitaxial layer 01, a light emitting layer 03 and a second type epitaxial layer 02 from top to bottom. The material of the semiconductor substrate 00″ can be GaN, GaAs, etc. The epitaxial structure is grown on the substrate 00″.

Referring to FIG. 24, step 2 includes forming a photonic crystal structure array in the epitaxial structure by etching the epitaxial structure.

Herein, the first type epitaxial layer 01, the light emitting layer 03 and the second type epitaxial layer 02 are etched in order from top down and stopped on the top of the semiconductor substrate 00″ by a plasma etching process, so the photonic crystal structure array 10 is formed through the whole mesa structure from top to bottom. Preferably, the power for etching is 200 W˜800 W, the time for etching is 50 S˜300 S.

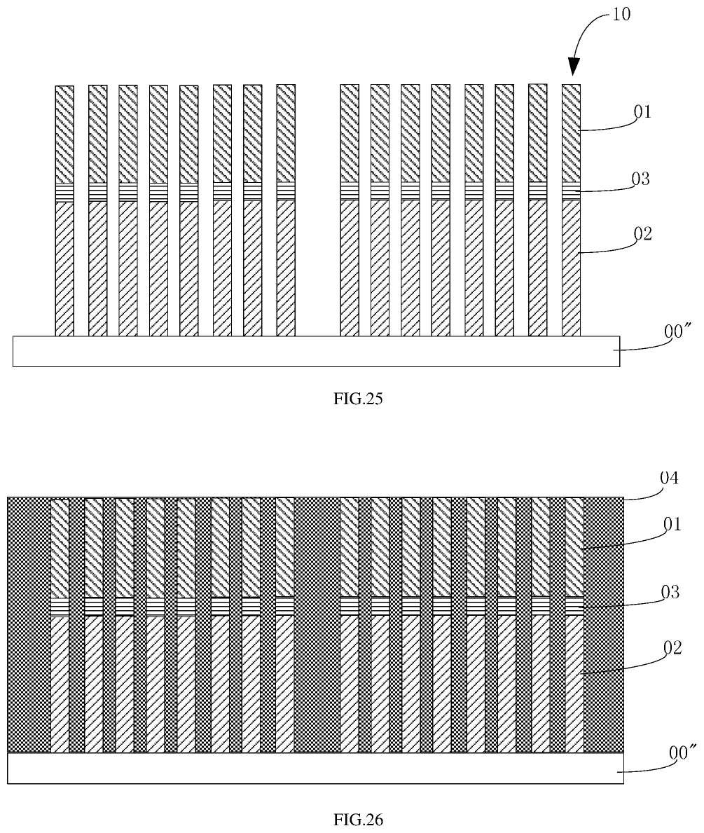

Referring to FIG. 25, step 3 includes forming a space to define a mesa structure by etching the photonic crystal structures.

Herein, the photonic crystal structure array is further etched by a conventional plasma etching process to define a mesa structure. In some embodiments, a space is formed between the adjacent mesa structures.

Referring to FIG. 26, step 4 includes forming a re-growth layer 04 on the sidewall of the photonic crystal structures and fully filled in the space between the adjacent mesa structures.

Herein, in this re-growth process, the temperature is 400° C. to 1000° C., the re-growth time is 5 seconds to 1000 seconds. Herein, the material for re-growth process is preferably the same as the material of the first type epitaxial layer and/or the material of the second type epitaxial layer but without intentional doping ions. The re-growth layer is firstly grown on the sidewall of each of the photonic crystal structures and the top of the photonic crystal structures. Then, the re-growth layer 04 on the top of the photonic crystal structures is removed by a chemical mechanical polishing method. In some embodiments, herein, the re-growth layer is further fully filled in the gap between the adjacent photonic crystal structures.

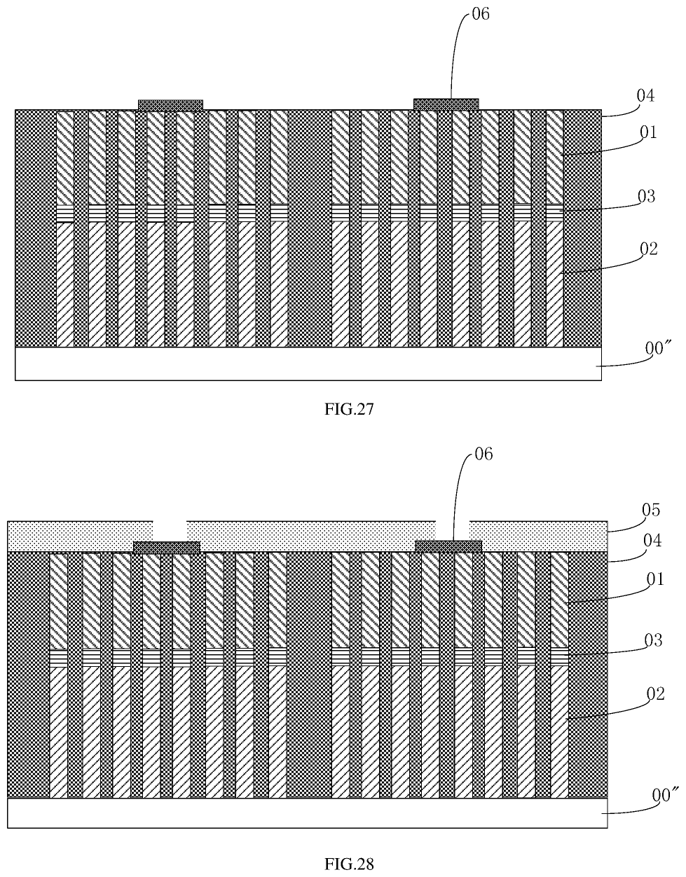

Referring to FIG. 27, step 5 includes forming a bottom contact 09 on the top of the photonic crystal structure array.

Herein, the bottom contact 06 is deposited on the top of the crystal structures array and on the top of the re-growth layer 04 by a conventional physical vapor deposition method with a photoresist mask protecting the other region, and then the mask is removed by a conventional wet etching method.

Referring to FIG. 28, step 6 includes forming a dielectric layer 05 on the top of the photonic crystal structure array and on the top of the re-growth layer 04, and covering the bottom contact 06.

Herein, the dielectric layer 05 is firstly deposited on the top of the re-growth layer 04, on the top of the photonic crystal structure array and covers the bottom contact 06 by a conventional chemical vapor deposition method.

Then, an opening is formed in the dielectric layer 05 by a conventional plasma etching method to expose the bottom contact 06.

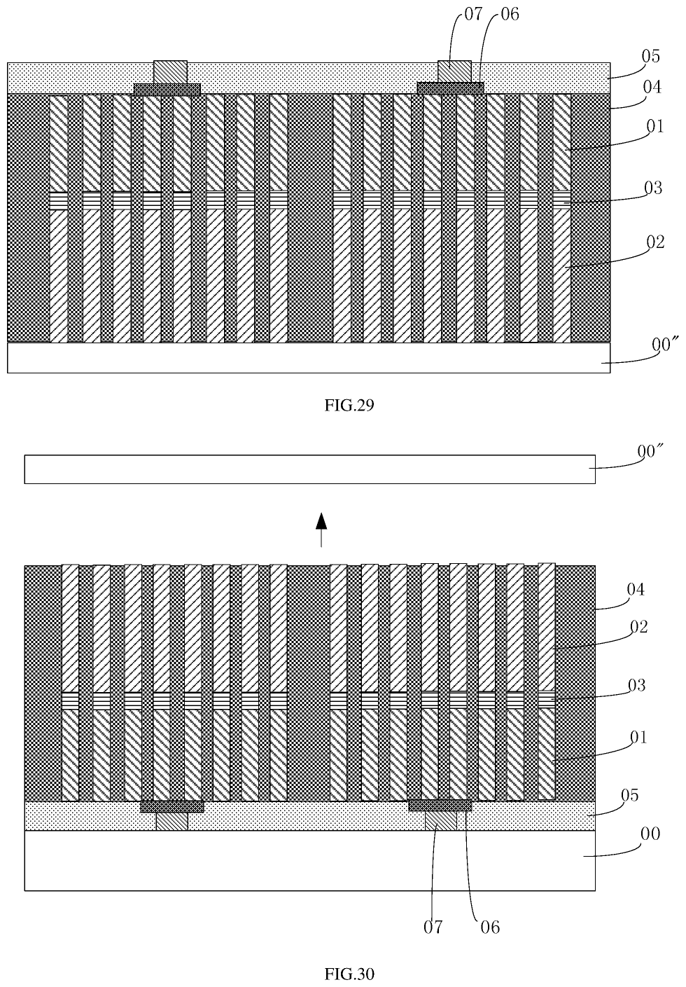

Referring to FIG. 29, step 7 includes forming a bottom connected structure 07 on the top of the bottom contact 06.

Herein, the conductive material is deposited into the opening to form a bottom connected pillar by a physical vapor process. The conductive materials can be conventional metals in the embodiment.

Referring to FIG. 30, step 8 includes bonding the bottom connected structure 07 with an IC backplane 00 by turning the semiconductor substrate 00″ upside down. Then, removing the semiconductor substrate 00″.

Herein, the semiconductor substrate 00″ with the epitaxial structure is firstly turned upside down. Then, the bottom connected structure 07 is bonded with a pad of the IC backplane 00. After the bonding process, the semiconductor substrate 00″ is removed by a conventional removing process, such as a laser lift-off method.

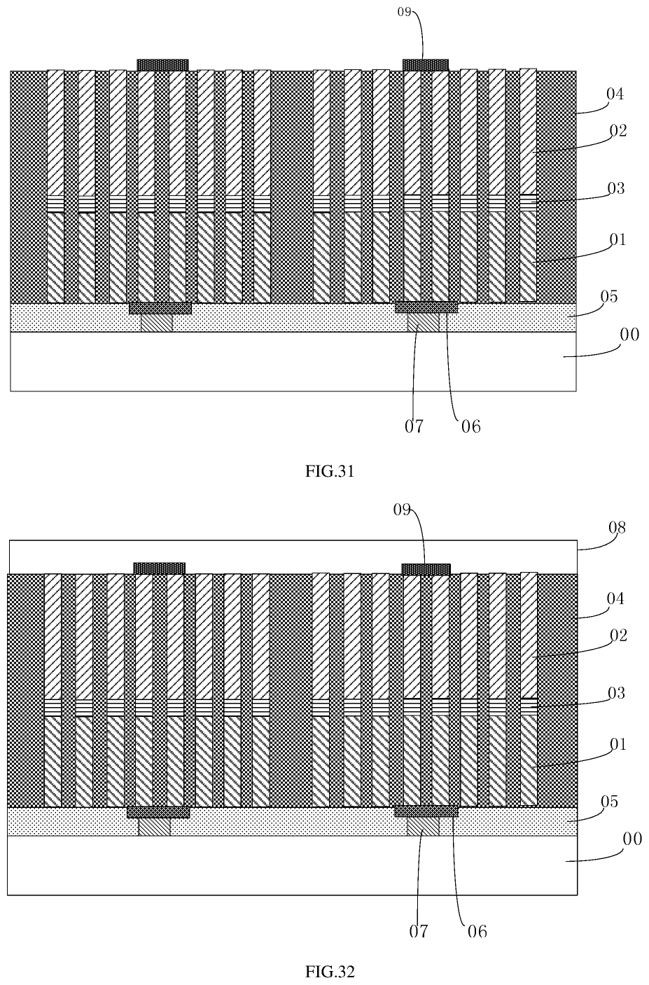

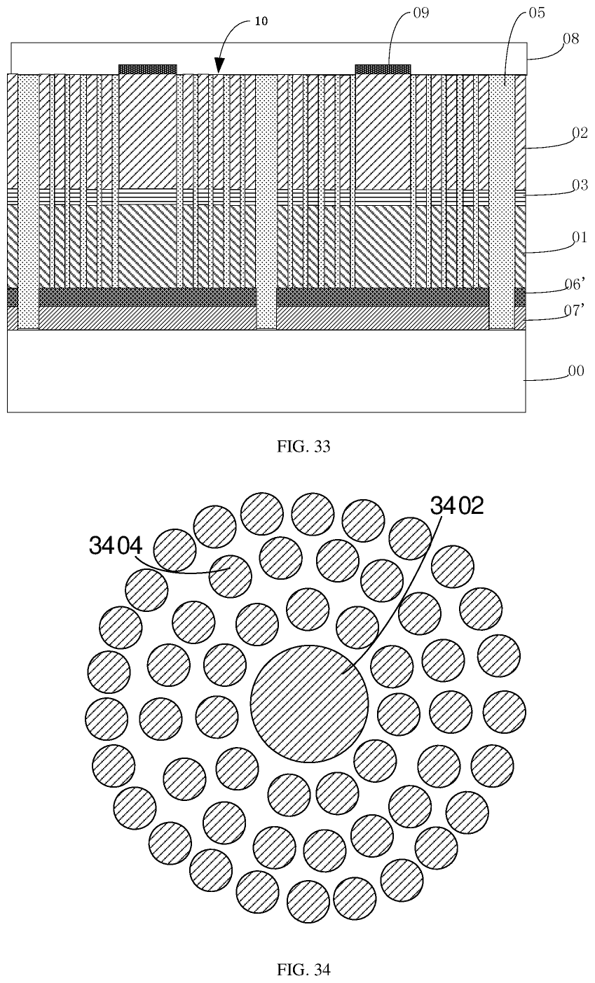

Referring to FIGS. 31 and 32, step 9 includes forming a top contact 09 and a top conductive layer 08 on the top of the dielectric layer 05 and the top of the mesa structure.

Herein, referring to FIG. 31, the top contact 09 is deposited on the top of the second type epitaxial layer 02 with a mask protecting the other region, and then the mask is removed. Then, referring to FIG. 32, a top conductive layer 08 is deposited on the second epitaxial layer 02 by a conventional vapor deposition process. Herein, the top conductive layer 08 is formed on the top of the photonic crystal structures, on the top of the re-growth layer 04 and covers the top contact 09.

### The Fourth Embodiment

To resolve the problem in the related technologies, a micro LED panel is provided in the embodiments of the present disclosure.

The micro LED panel comprises a micro LED array. FIG. 33 is a sectional structure diagram of another micro LED panel according to some embodiments (for example, the fourth embodiment) of the present disclosure.

Referring to FIG. 33, the micro LED structure in the micro LED array at least comprises: a mesa structure and a photonic crystal structure array. The mesa structure from bottom to top comprises a first type epitaxial layer 01, a light emitting layer 03 and a second type epitaxial layer 02. The photonic crystal structure array is formed through the mesa structure. A gap is between the adjacent photonic crystal structures 10. Herein, the top of the photonic crystal structures are the top of the mesa structure and the bottom of the photonic crystal structures are the bottom of the mesa structure. Additionally, to achieve high image quality, the width of the mesa structure is not more than 3 μm.

FIG. 34 is a top view of the mesa structure in FIG. 33 according to some embodiments (for example, the fourth embodiment) of the present disclosure.

Furthermore, referring to FIG. 34, the photonic crystal structure array comprises a center photonic crystal structure 3402. The other photonic crystal structures, for example, 3404, are formed around the center of the photonic crystal structure. Additionally, the diameter of the center photonic crystal structure 3402 is greater than the diameter of each of the other photonic crystal structures, such as 3404.

Additionally, in some embodiments, the photonic crystal structure 10 is one dimensional nano-structure. Multiple of the one dimensional nano-structures are distributed in an array. The one dimensional nano-structures are formed in the mesa structure along the light emitting direction. Furthermore, the one dimensional nano-structures are formed perpendicular to the light emitting layer 03. The one dimensional nano-structure is like a nanowire, nanorod, nanofiber, etc. Preferably, the diameter of the one dimensional nano-structures is not more than 1000 nm.

Referring to FIG. 33, a dielectric layer 05 is filled in the gap between the adjacent photonic crystal structures. Furthermore, the dielectric layer 05 can be further formed on the sidewall of the mesa structure. Preferably, the material of the dielectric layer 05 is selected from one or more of SiO₂, SiNx, Al₂O₃, AlN, HfO₂, TiO₂, and/or ZrO₂, etc. The dielectric layer 05 in the gap between the adjacent photonic crystal structures is transparent and electrically isolated. Additionally, the dielectric layer 05 is further formed in the space between the adjacent mesa structures, even fully filled in the space between the adjacent mesa structures.

In some embodiments, the top contact 09 is formed on the top of the mesa structure and a top conductive layer 08 is formed on the top contact 09 and the top of the mesa structure. Herein, the top conductive layer 08 is continuously formed on the whole micro LED structures array. Additionally, when the top of the dielectric layer 05 is lower than the top of the photonic crystal structures, the top conductive layer 08 is filled in some of the gap between the adjacent photonic crystal structures; and, the bottom of the top contact 09 is filled in some of the gap between the adjacent photonic crystal structures. Herein, the light emitting direction is from bottom to top, so the top conductive layer 08 is transparent.

The bottom contact layer 06′ is formed at the bottom surface of the first type epitaxial layer 02. The conductive type of the bottom contact is the same as that of the first type epitaxial layer 01, such as, the first type epitaxial layer 01 is P type, the bottom contact layer 06′ is also P type. Furthermore, since the light emits upward or downward from the mesa structure, the diameter of the bottom contact layer 06′ is larger than the diameter of the top contact 09. While the diameter of the top contact 09 can be as small as possible, the top contact 09 can also be as small as a dot on the top surface of the second type epitaxial layer 02. In another embodiment, the diameter of the bottom contact layer 06′ can also be equal to or smaller than the diameter of the top contact 09. A bottom connected layer 07′ is formed at the bottom of the bottom contact layer 06′. The bottom connected layer 07′ is used for connecting with the bottom electrode such as the contact pad in an IC backplane 00. Furthermore, the diameter of the bottom connected structure 07 is 20 nm to 1 μm. Preferably, the diameter of the bottom connected layer 07′ is 800 nm to 1 μm. Furthermore, the center of the bottom contact layer 06′ is aligned with the center of the top contact 09 in the vertical direction. Additionally, the material of the bottom contact layer 06′ and the bottom connected layer 07′ are transparent conductive material, such as ITO, or FTO, etc. Additionally, the material of the bottom contact layer 06′ and the bottom connected layer 07′ are not transparent. The material of the bottom contact layer 06′ and the bottom connected layer 07′ can be conductive metal. Preferably, the material of the bottom contact layer 06′ can be selected from at least one of Au, Zn, Be, Cr, Ni, Ti, Ag and Pt. The material of the bottom connected layer 07′ can be selected from at least one of Au, Zn, Be, Cr, Ni, Ti, Ag and Pt.

In some embodiments, herein the center of the bottom contact layer 06′ is vertically aligned with the center of the first type epitaxial layer 01. But, in another embodiment, the center of the bottom contact layer 06′ is not vertically aligned with the center of the first type epitaxial layer 01.

The method of manufacturing the aforementioned micro LED panel in this fourth embodiment comprises the following steps:

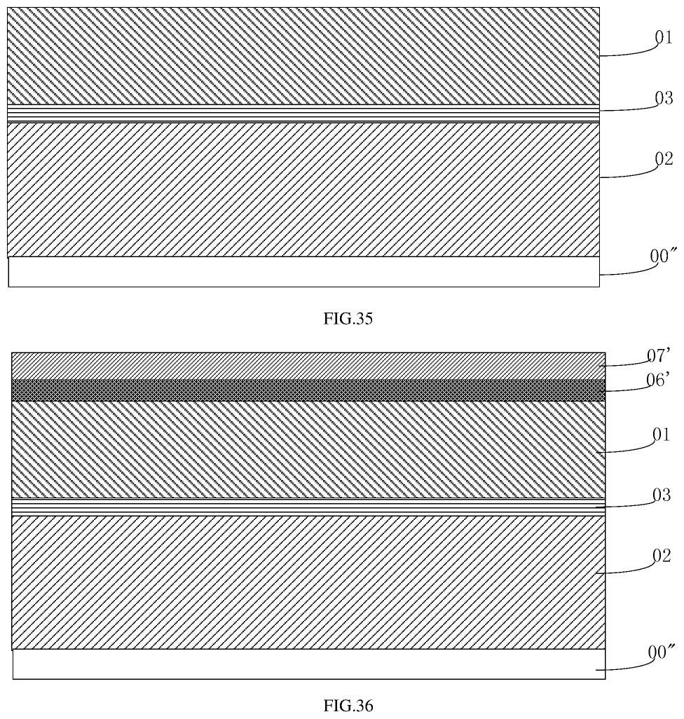

FIGS. 35 to 42 separately illustrate the steps of a method of manufacturing the micro LED panel according to some embodiments (for example, the fourth embodiment).

Referring to FIG. 35, step 1 includes supplying a semiconductor substrate 00″ with an epitaxial structure.

Herein, the epitaxial structure comprises a first type epitaxial layer 01, a light emitting layer 03 and a second type epitaxial layer 02 from top to bottom. The material of the semiconductor substrate 00″ can be GaN, GaAs, etc. The epitaxial structure is grown on the substrate 00″.

Referring to FIG. 36, step 2 includes forming a bottom contact layer 06′ and a bottom connected layer 07′ in order on the top surface of the first type epitaxial layer 01.

Herein, the bottom contact layer 06′ and the bottom connected layer 07′ are deposited in order by a conventional physical vapor deposition method. The bottom connected layer 07′ is also as a metal bonding layer for a subsequent metal bonding process in step 3.

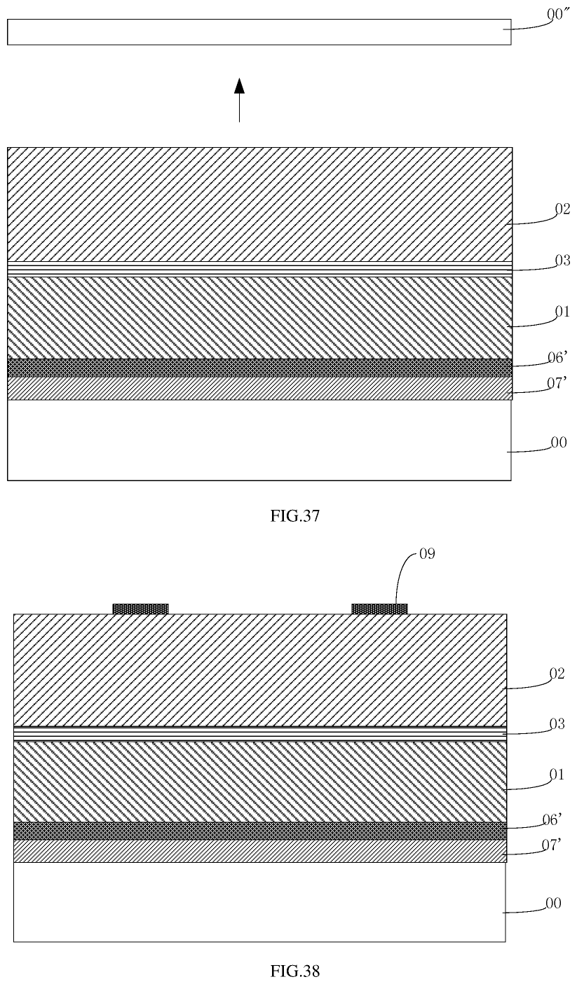

Referring to FIG. 37, step 3 includes bonding the bottom connected layer 07′ with an IC backplane 00 by turning the semiconductor substrate 00″ upside down. Then, removing the semiconductor substrate 00″.

Herein, the semiconductor substrate 00″ with the epitaxial structure is firstly turned upside down. Then, the bottom connected layer 07′ is bonded with pads of the IC backplane 00. After the bonding process, the semiconductor substrate 00″ is removed by a conventional removing process, such as a laser lift-off method.

Referring to FIG. 38, step 4 includes forming a top contact 09 on the top of the second type epitaxial layer 02.

Herein, the top contact 09 is deposited on the top of the second type epitaxial layer 02 by a conventional physical vapor deposition process with a mask protecting the other region, and then the mask is removed by a conventional wet etching process.

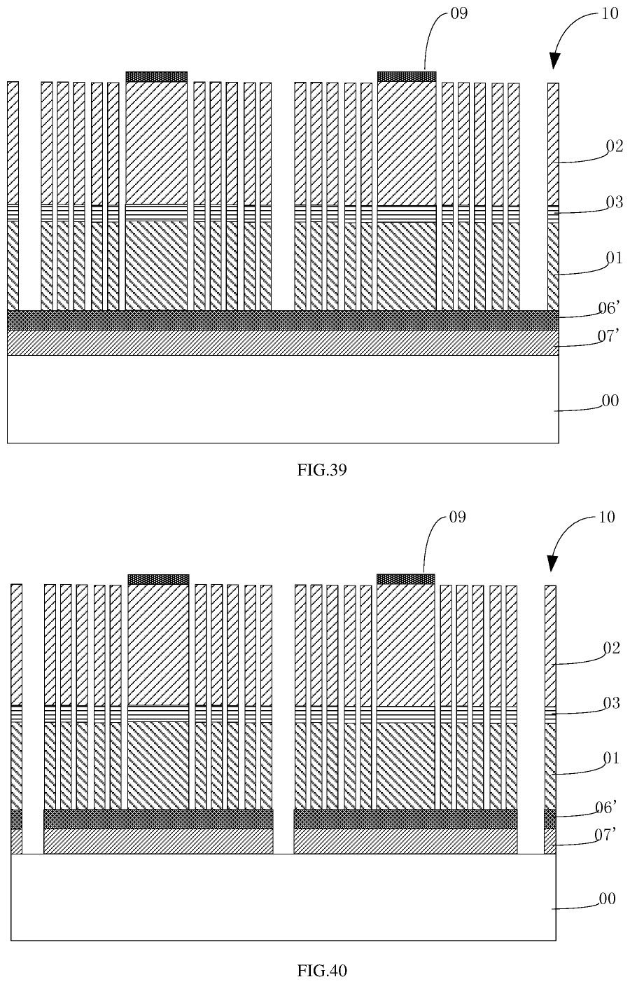

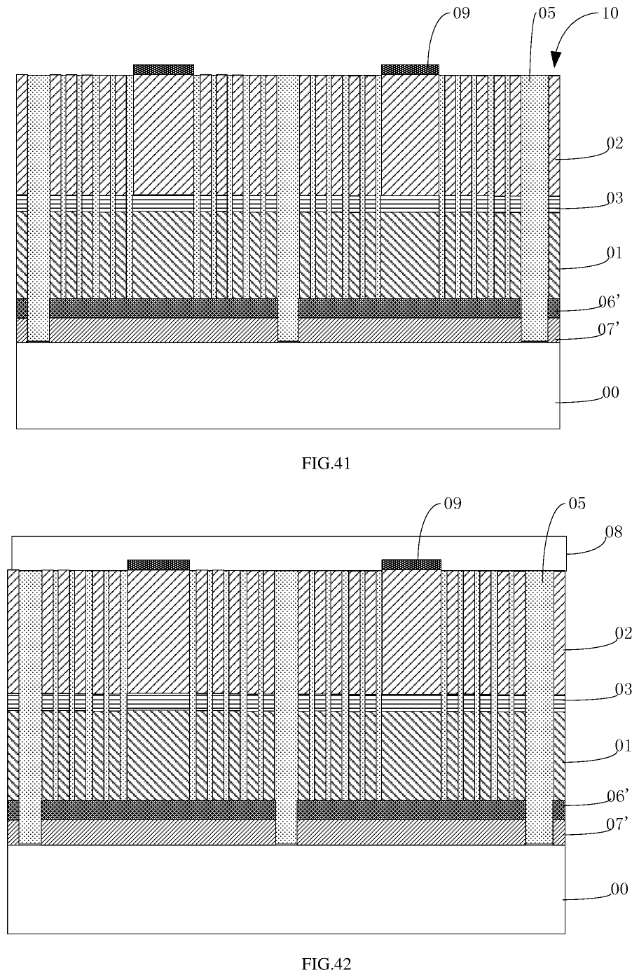

Referring to FIGS. 39 and 40, step 5 includes forming a mesa structure in the epitaxial structure by etching the epitaxial structure, the bottom contact layer 06′ and the bottom connected layer 07′ from top to bottom; and, forming a photonic crystal structure array by etching the epitaxial structure.

Herein, referring to FIG. 39, the second type epitaxial layer 02, the light emitting layer 03 and the first type epitaxial layer 01 are etched in order from top down and stopped on the top of the bottom contact layer 06′ by a plasma etching process, so the mesa structures are formed on the bottom contact layer 06′, and the photonic crystal structure array is formed through the whole mesa structure from top to bottom. Then, referring to FIG. 40, the bottom contact layer 06′ and the bottom connected layer 07′ are further etched from top to bottom, so that the bottom of the space extends to the top of the IC backplane 00; therefore, the bottom connected layer 06′ and the bottom contact layer 07′ are isolated by the space.

In the etching process of step 5, the center photonic crystal structure is formed under the top contact 09 which is not etched. The diameter of the center photonic crystal structure is greater than the diameter of each of the other photonic crystal structures. Preferably, the power for etching is 200 W˜800 W, the time for etching is 50 S˜300 S.

Referring to FIG. 41, step 6 includes forming a dielectric layer 05 on the sidewall of the photonic crystal structures.

Herein, the dielectric layer 05 is deposited on the sidewall of the photonic crystal structures by a conventional chemical vapor deposition method. The dielectric layer 05 is further fully filled in the gap between the adjacent photonic crystal structures. Furthermore, the dielectric layer 05 is formed in the space between the adjacent mesa structures. Preferably, the dielectric layer 05 is fully filled in the space between the adjacent mesa structures. In another embodiment, the dielectric layer 05 is only formed on the sidewall of the mesa structures and not fully filled in the space between the adjacent mesa structures.

Referring to FIG. 42, step 7 includes forming a top contact 09 and a top conductive layer 08 on the top of the dielectric layer 05 and the top of the mesa structure.

Herein, the top contact 09 is deposited on the top of the second type epitaxial layer 02 with a mask protecting the other region, and then the mask is removed. Then, a top conductive layer 08 is deposited on the second epitaxial layer 02 by a conventional vapor deposition process. Herein, the top conductive layer 08 is formed on the top of the photonic crystal structures, on the top of the dielectric layer 05 and covers the top contact 09. In another embodiment, the dielectric layer 05 is only formed on the sidewall of the mesa structures and not fully filled in the space, so the top conductive layer 08 is further formed in the space between the adjacent mesa structures.

In another embodiment, referring to FIG. 11, the top conductive layer 08 is not connected with each other between the adjacent mesa structures.

FIG. 43 illustrates another step 6 of depositing a dielectric layer according to some embodiments (for example, the fourth embodiment).

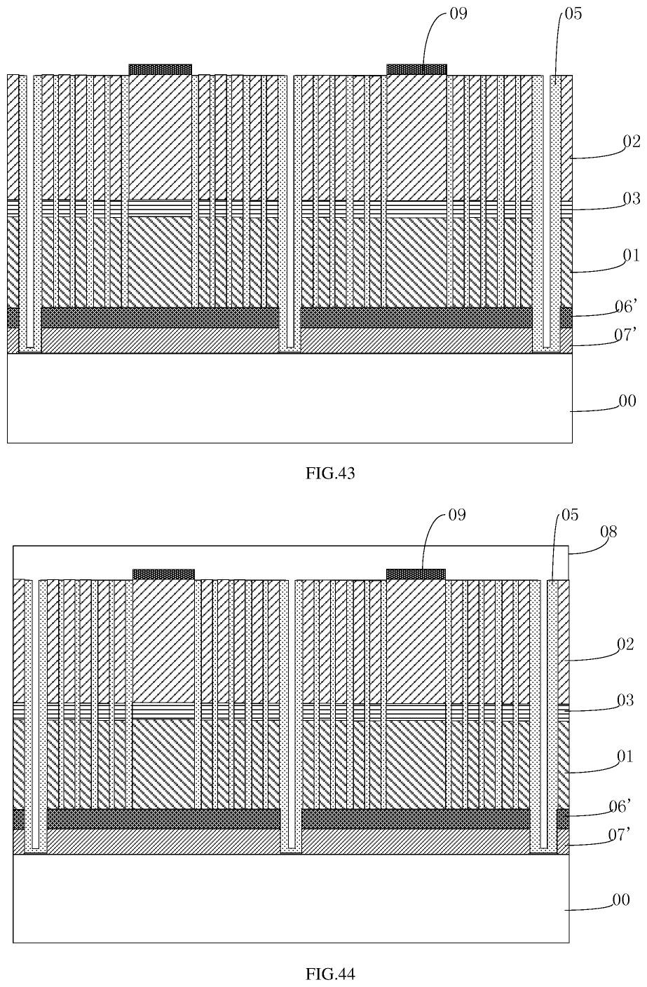

FIG. 44 is a sectional structure diagram of another micro LED panel according to some embodiments (for example, the fourth embodiment) of the present disclosure.

In another embodiment, referring to FIG. 43, in step 6, the dielectric layer 05 is only formed on the sidewall of the mesa structures and not fully filled in the space. Therefore, in step 7, referring to FIG. 44, the top conductive layer 08 is further formed in the space between the adjacent mesa structures.

### The Fifth Embodiment

To resolve the problem in the related technologies, a micro LED panel is provided in the embodiments of the present disclosure.

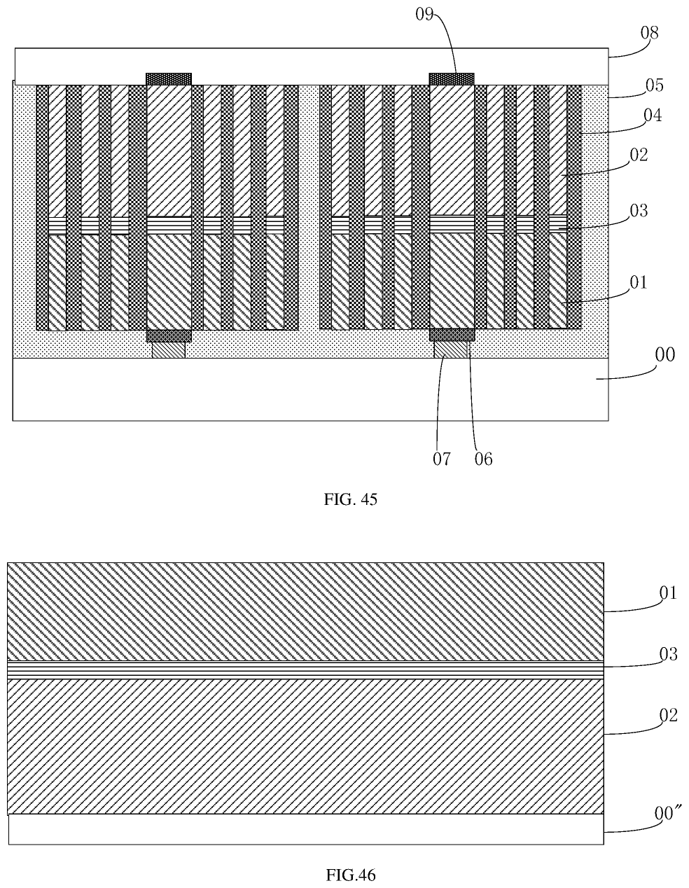

The micro LED panel comprises a micro LED array. Referring to FIG. 45, the micro LED structure in the micro LED array at least comprises: a mesa structure and a photonic crystal structure array. The mesa structure from bottom to top comprises a first type epitaxial layer 01, a light emitting layer 03 and a second type epitaxial layer 02. The photonic crystal structure array is formed through the mesa structure. A gap is between the adjacent photonic crystal structures 10. Herein, the top of the photonic crystal structures are the top of the mesa structure and the bottom of the photonic crystal structures are the bottom of the mesa structure. Additionally, to achieve high image quality, the width of the mesa structure is not more than 3 μm.

Furthermore, referring to FIG. 34, the photonic crystal structure array comprises a center photonic crystal structure; the other photonic crystal structures are formed around the center of the photonic crystal structure. Additionally, the diameter of the center photonic crystal structure is greater than the diameter of each of the other photonic crystal structures.

Additionally, the photonic crystal structure is a one dimensional nano-structure. Multiple of the one dimensional nano-structures are distributed in an array. The one dimensional nano-structures are formed in the mesa structure along the light emitting direction. Furthermore, the one dimensional nano-structures are formed perpendicular to the light emitting layer 03. The one dimensional nano-structure is like a nanowire, nanorod, nanofiber, etc. Preferably, the diameter of the one dimensional nano-structures is not more than 1000 nm.

A re-growth layer 04 is formed at least part of the sidewall of the mesa structure. Herein, the re-growth layer is formed on the sidewall of the whole mesa structure. In another embodiment, the re-growth layer is formed at least part of the sidewall of the first type epitaxial layer, the whole sidewall of the light emitting layer and at least part of the sidewall of the first type epitaxial layer. In some embodiments, the re-growth layer can be formed on at least part of the sidewall of the first type epitaxial layer and the whole sidewall of the light emitting layer; or, the re-growth layer can be formed on at least part of the sidewall of the second type epitaxial layer and the whole sidewall of the light emitting layer; or, the re-growth layer can be formed on at least part of the sidewall of the light emitting layer.

Referring to FIG. 45 again, the re-growth layer 04 is further formed at the sidewall of the photonic crystal structures. Preferably, the re-growth layer 04 is fully filled in the gap between the adjacent photonic crystal structures.

Furthermore, the re-growth layer 04 which is formed on the sidewall of the light emitting layer 03 is not parallel to the extending direction of the light emitting layer 03. Furthermore, the light emitting layer 03 comprises a top surface, an edge surface and a bottom surface; and, the re-growth layer 04 is only grown on the edge surface of the light emitting layer 03 but not grown on the top surface and the bottom surface of the light emitting layer 03. Preferably, the inclined angle of the re-growth layer 04 on the sidewall of the light emitting layer is 30 to degrees to 90 degrees relative to the extending direction of the light emitting layer relative to the horizontal direction of light emitting layer 03. That is to say, the re-growth layer 04 is grown on the end surface of the light emitting layer 03, not grown on the top and bottom of the light emitting layer 03. Additionally, the light emitting layer 03 comprises a plurality of pairs of quantum wells; the re-growth layer 04 is not parallel to the surface of each of the plurality of pairs of quantum wells. Herein, the light emitting layer 03 has a straight line shape without any bending. Preferably, the diameter of the mesa structure is not more than 3 μm. Furthermore, the bottom of the photonic crystal structure array is aligned with the bottom of the mesa structures, and the top of the photonic crystal structure array is aligned with the top of the re-growth layer 04.

Herein, the material of the re-growth layer 04 with intrinsic doped ions is the same as the material of the first type epitaxial layer 01 or the material of the second type epitaxial layer 02 but without intentional doping ions. The material of the re-growth layer 04 must be lattice matched with the light emitting layer 03, the first type epitaxial layer 01 or the second type epitaxial layer 02. Preferably, the material of the re-growth layer 04 is monocrystal, the material of the first epitaxial layer 01 is monocrystal and the material of the second epitaxial layer 02 is monocrystal. Furthermore, the material of the re-growth layer 04 is one or more of GaAs, InGaAs, GaP, GaN, InGaN, AlGaN, AlInP, GaInP, AlGaInP, AlP, InP, AlN, and/or InN, etc., or any combinations thereof, preferably one or more of GaP, AlP, GaAs, InP, AlInP, GaInP, AlN, GaN, and/or InN, or any combinations thereof. In another embodiment, the material of the re-growth layer 04 is without intentional doping ions and is not the same as the same as the material of the first type epitaxial layer or the material of the second type epitaxial layer 02.

The resistance of the re-growth layer 04 is higher than the resistance of the light emitting layer 03 and the re-growth layer 04 is not electrically conductive, thereby ensuring the normal work of the micro LED structures, and stopping the carries spreading outside the light emitting layer 03. Preferably, the band gap of the re-growth layer 04 is greater than the band gap of the light emitting layer 03. Furthermore, the thickness of the re-growth layer 04 is less than the thickness of the light emitting layer 03, preferably, the thickness of the re-growth layer 04 is not more than 100 nm.

FIG. 45 is a sectional structure diagram of a micro LED panel according to some embodiments (for example, the fifth embodiment) of the present disclosure.

Referring to FIG. 45, a dielectric layer 05 is further formed in the space between the adjacent mesa structures. Preferably, the dielectric layer 05 is fully filled in the space between the adjacent mesa structures. The dielectric layer 05 is preferably transparent and electrically isolated. Preferably, the material of the dielectric layer 05 is selected from one or more of SiO₂, SiNx, Al₂O₃, AlN, HfO₂, TiO₂, and/or ZrO₂, etc.

A top contact 09 is formed on the top of the mesa structure and a top conductive layer 08 is formed on the top contact 09 and the top of the mesa structure. Herein, the top conductive layer 08 is continuously formed on the whole micro LED structures array. Additionally, when the top of the dielectric layer 05 is lower than the top of the photonic crystal structures, the top conductive layer 08 is filled in some of the gap between the adjacent photonic crystal structures; and, the bottom of the top contact 09 is filled in some of the gap between the adjacent photonic crystal structures. Herein, the light emitting direction is from bottom to top, so the top conductive layer 08 is transparent.

A bottom contact 06 is formed at the bottom surface of the first type epitaxial layer 02. The conductive type of the bottom contact is the same as that of the first type epitaxial layer 01, such as, the first type epitaxial layer 01 is P type, and the bottom contact 06 is also P type. Furthermore, since the light emits upward or downward from the mesa structure, the diameter of the bottom contact 06 is larger than the diameter of the top contact 09. While the diameter of the top contact 09 can be as small as possible, the top contact 09 can also be as small as a dot on the top surface of the second type epitaxial layer 02. In another embodiment, the diameter of the bottom contact 06 can also be equal to or smaller than the diameter of the top contact 09. A bottom connected structure 07 is formed at the bottom of the bottom contact 06. The bottom connected structure 07 is used for connecting with the bottom electrode such as the contact pad in an IC backplane 00. Furthermore, the diameter of the bottom connected structure 07 is 20 nm to 1 μm. Preferably, the diameter of the bottom connected structure 07 is 800 nm to 1 μm. Furthermore, the center of the bottom contact 06 is aligned with the center of the top contact 09 in the vertical direction. Additionally, the material of the bottom contact 06 and the bottom connected structure 07 are transparent conductive material, such as ITO, or FTO, etc. Additionally, the material of the bottom contact 06 and the bottom connected structure 07 are not transparent. The material of the bottom contact 06 and the bottom connected structure 07 can be conductive metal. Preferably, the material of the bottom contact 06 can be selected from at least one of Au, Zn, Be, Cr, Ni, Ti, Ag and Pt. The material of the bottom connected structure 07 can be selected from at least one of Au, Zn, Be, Cr, Ni, Ti, Ag and Pt.

In some embodiments, the center of the bottom contact 06 is vertically aligned with the center of the first type epitaxial layer 01. But, in another embodiment, the center of the bottom contact 06 is not vertically aligned with the center of the first type epitaxial layer 01.

The method of manufacturing the aforementioned micro LED panel in this fifth embodiment comprises the following steps.

FIGS. 46 to 54 separately illustrate the steps of a method of manufacturing the micro LED panel according to some embodiments (for example, the fifth embodiment).

Referring to FIG. 46, step 1 includes supplying a semiconductor substrate 00″ with an epitaxial structure.

Herein, the epitaxial structure comprises a first type epitaxial layer 01, a light emitting layer 03 and a second type epitaxial layer 02 from top to bottom. The material of the semiconductor substrate 00′ can be GaN, GaAs, etc. The epitaxial structure is grown on the substrate 00′.

Referring to FIG. 47, step 2 includes forming a bottom contact 06 on the top of the epitaxial structure.

Herein, the bottom contact 06 is deposited on the top of the second type epitaxial layer 02 by a conventional physical vapor deposition method with a mask protecting the other region, and then the mask is removed by a conventional wet etching process.

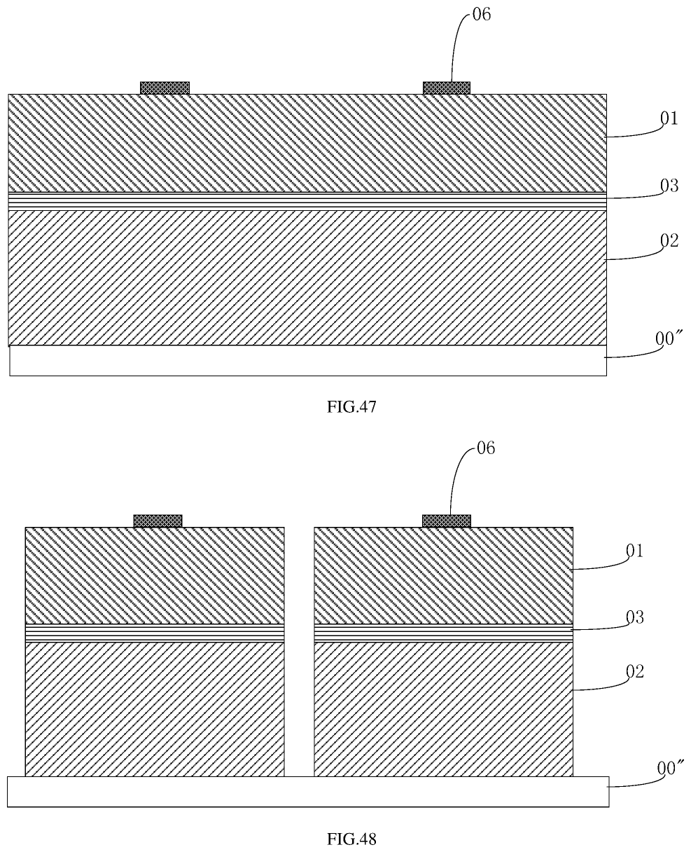

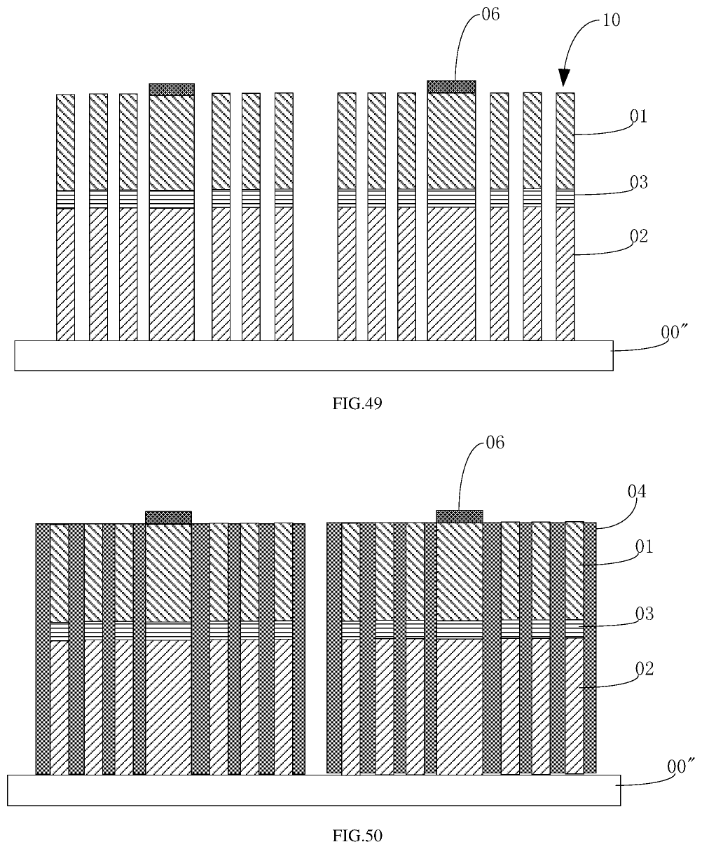

Referring to FIG. 48, step 3 includes forming a mesa structure by patterning the epitaxial structure.

Herein, the epitaxial structure is etched from top down by a conventional plasma etching method, to from mesa structures on the semiconductor substrate 00″.

Referring to FIG. 49, step 4 includes forming a photonic crystal structure array with individual photonic crystal structure, such as 10 in the mesa structure.

Herein, the first type epitaxial layer 01, the light emitting layer 03 and the second type epitaxial layer 02 are etched in order from top down and stopped on the top of the semiconductor substrate 00″ by a plasma etching process, so the photonic crystal structure array 10 is formed through the whole mesa structure from top to bottom. Preferably, the power for etching is 200 W˜800 W, the time for etching is 50 S˜300 S.

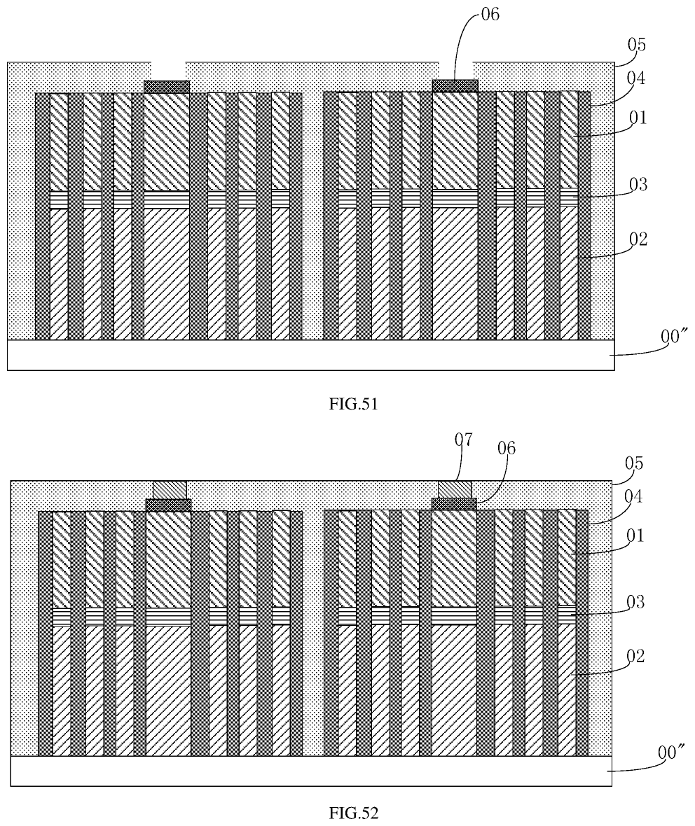

Referring to FIG. 50, step 5 includes forming a re-growth layer 04 on the sidewall of the photonic crystal structures.

Herein, in this re-growth process, the temperature is 400° C. to 1000° C., the re-growth time is 5 seconds to 1000 seconds. Herein, the material for re-growth process is preferably the same as the material of the first type epitaxial layer and/or the material of the second type epitaxial layer but without intentional doping ions. The re-growth layer is firstly grown on the sidewall of each of the photonic crystal structures and the top of the photonic crystal structures. Then, the re-growth layer on the top of the photonic crystal structures is removed by a conventional chemical mechanical polishing method. In some embodiments, herein, the re-growth layer is fully filled in the gap between the adjacent photonic crystal structures, but not fully filled in the space between the adjacent mesa structures.

Referring to FIG. 51, step 6 includes forming a dielectric layer 05 on the top of the mesa structure, on the top of the re-growth layer 04 and covering the bottom contact 06.

Herein, the dielectric layer 05 is firstly deposited on the top of the re-growth layer 04, on the top of the photonic crystal structure array and covers the bottom contact 06 by a conventional chemical vapor deposition method.

Then, an opening is formed in the dielectric layer 05 by a conventional plasma etching method to expose the bottom contact 06.

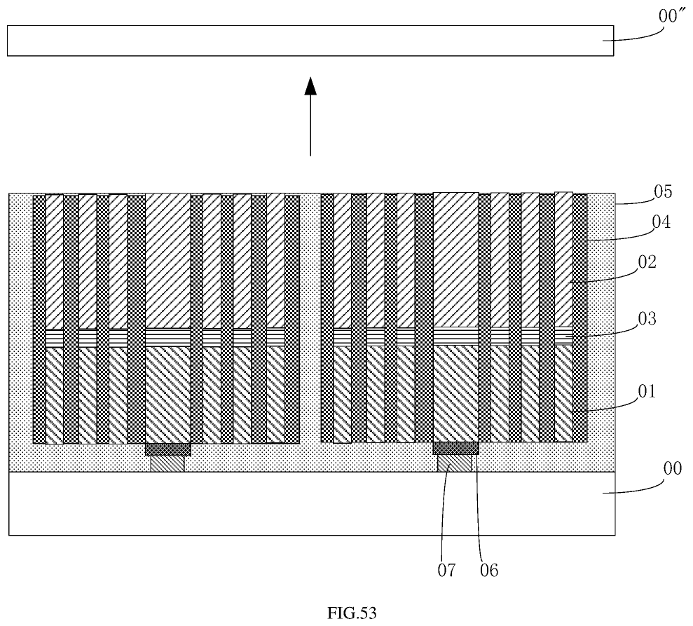

Referring to FIG. 52, step 7 includes forming a bottom connected structure 07 on the top of the bottom contact 06.

Herein, the conductive material is deposited into the opening to form a bottom connected pillar by a physical vapor process. The conductive materials can be conventional metals in the embodiment.

Referring to FIG. 53, step 8 includes bonding the bottom connected structure 07 with an IC backplane 00 by turning the semiconductor substrate 00″ upside down. Then, removing the semiconductor substrate 00″.

Herein, the semiconductor substrate 00″ with the epitaxial structure is firstly turned upside down. Then, the bottom connected structure 07 is bonded with a pad of the IC backplane 00. After the bonding process, the semiconductor substrate 00″ is removed by a conventional removing process, such as a laser lift-off method.

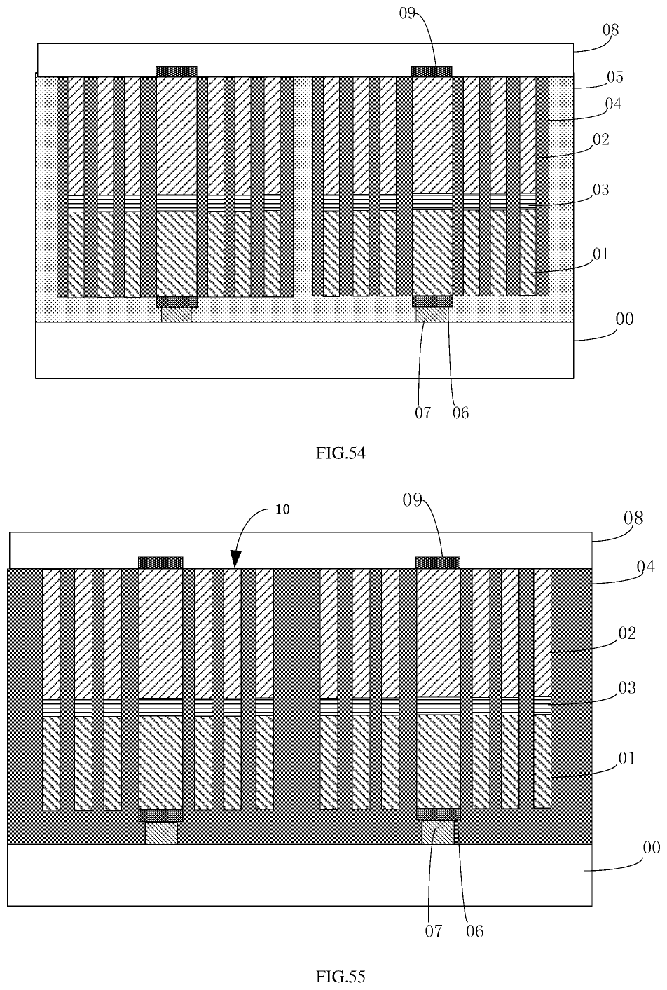

Referring to FIG. 54, step 9 includes forming a top contact 09 and a top conductive layer 08 on the top of the dielectric layer 05, on the top of the re-growth layer 04 and on the top of the mesa structure.

Herein, the top contact 09 is deposited on the top of the second type epitaxial layer 02 with a mask protecting the other region, and then the mask is removed. Then, a top conductive layer 08 is deposited on the second epitaxial layer 02 by a conventional vapor deposition process. Herein, the top conductive layer 08 is formed on the top of the photonic crystal structures, on the top of the dielectric layer 05 and covers the top contact 09.

In another embodiment, the dielectric layer 05 is only formed on the sidewall of the mesa structures and not fully filled in the space between the adjacent mesa structures, so the top conductive layer 08 is further formed in the space between the adjacent mesa structures.

### The Sixth Embodiment

FIG. 55 is a sectional structure diagram of a micro LED panel according to some embodiments (for example, the sixth embodiment) of the present disclosure.

Referring to FIG. 55, the difference of the sixth embodiment from the fifth embodiment is as follows: the re-growth layer 04 is fully filled in the space between the adjacent mesa structures. Other details of the micro LED panel can be referred to the fifth embodiment, which will not be repeated herein.

The method of manufacturing the aforementioned micro LED panel in this sixth embodiment comprises the following steps:
step 1, supplying a semiconductor substrate 00″ with an epitaxial structure; step 2, forming a bottom contact 06 on the top of the epitaxial structure; step 3, forming a mesa structure by patterning the epitaxial structure; and step 4, forming a photonic crystal structure array with individual photonic crystal structure, such as 10, in the mesa structure.

In some embodiments, the detail of the steps 1 to 4 can be referred to the steps 1 to 4 of the fifth embodiment, which will not be described herein.

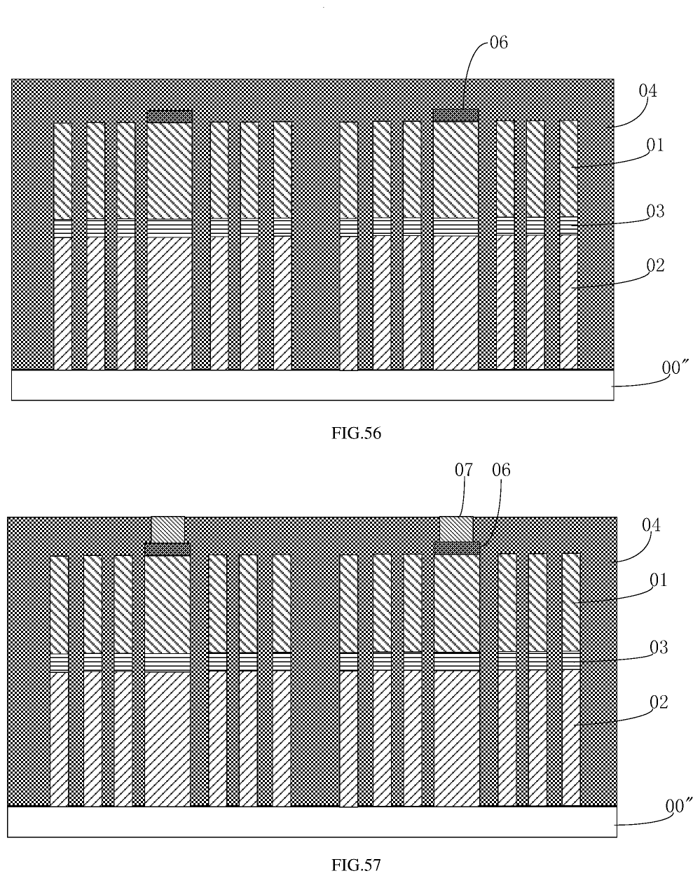

Referring to FIG. 56, step 5 includes forming a re-growth layer 04 on the sidewall and the top of the photonic crystal structures, in the space between the adjacent mesa structures and covering the bottom contact 06.

Herein, the re-growth layer 04 is firstly grown on the sidewall of each of the photonic crystal structures and the top of the photonic crystal structures. Then, the top surface of the re-growth layer 04 is planarized by a conventional chemical mechanical polishing method. In some embodiments, herein, the re-growth layer 04 is fully filled in the gap between the adjacent photonic crystal structures and fully filled in the space between the adjacent mesa structures. Furthermore, the top surface of the re-growth layer is higher than the top surface of the photonic crystal structure array and the top surface of the bottom contact 06.

In this re-growth process, the temperature is 400° C. to 1000° C., the re-growth time is 5 seconds to 1000 seconds. Herein, the material for re-growth process is preferably the same as the material of the first type epitaxial layer and/or the material of the second type epitaxial layer but without intentional doping ions.

Referring to FIG. 57, step 6 includes forming a bottom connected structure 07 on the top of the bottom contact 06.

Herein, before forming the bottom connected structure 07, an opening is formed in the re-growth layer 04 by a conventional plasma etching method to expose the bottom contact 06.

Then, the conductive material is deposited into the opening to form a bottom connected structure 07 by a physical vapor process. The conductive materials can be conventional metals in the embodiment. The bottom connected structure 07 is like a pillar herein.

Referring to FIG. 58, step 7 includes bonding the bottom connected structure 07 with an IC backplane 00 by turning the semiconductor substrate 00″ upside down. Then, removing the semiconductor substrate 00″.

Herein, the semiconductor substrate 00″ with the epitaxial structure is firstly turned upside down. Then, the bottom connected structure 07 is bonded with a pad of the IC backplane 00. After the bonding process, the semiconductor substrate 00″ is removed by a conventional removing process, such as a laser lift-off method.

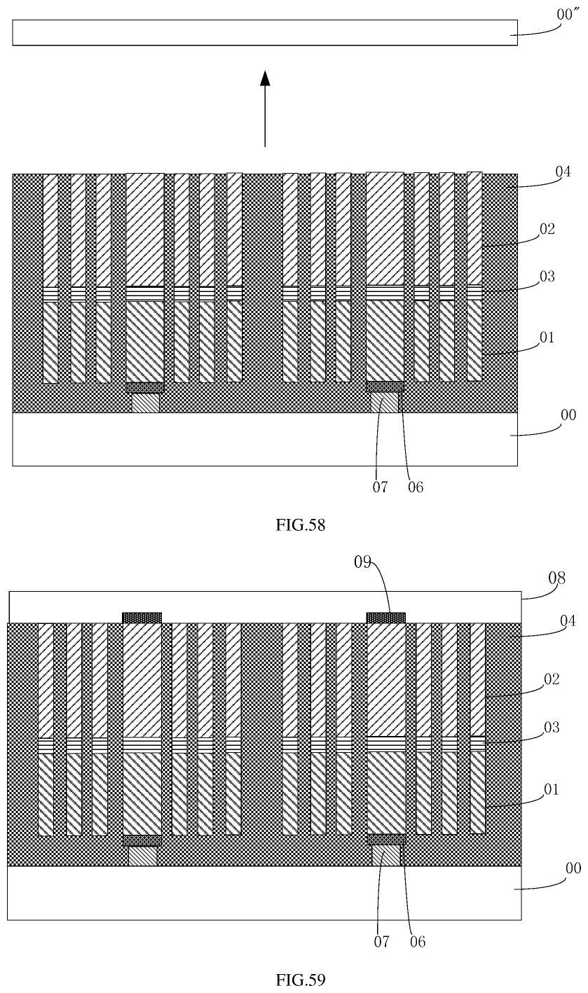

Referring to FIG. 59, step 8 includes forming a top contact 09 and a top conductive layer 08 on the top of the re-growth layer 04 and on the top of the mesa structure.

Herein, the top contact 09 is deposited on the top of the second type epitaxial layer 02 with a mask protecting the other region, and then the mask is removed. Then, a top conductive layer 08 is deposited on the second epitaxial layer 02 by a conventional vapor deposition process. Herein, the top conductive layer 08 is formed on the top of the photonic crystal structures, on the top of the re-growth layer 04 and covers the top contact 09.

It is understood by those skilled in the art that, the micro display panel is not limited by the structure mentioned above, and may include more or less components than those as illustrated, or some components may be combined, or a different component may be utilized.

It is understood by those skilled in the art that, all or part of the steps for implementing the foregoing embodiments may be implemented by hardware, or may be implemented by a program which instructs related hardware. The program may be stored in a flash memory, in a conventional computer device, in a central processing module, in an adjustment module, etc.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

Further embodiments also include various subsets of the above embodiments including embodiments as shown in FIGS. 1-59 combined or otherwise re-arranged in various other embodiments.

Although the detailed description contains many specifics, these should not be construed as limiting the scope of the invention but merely as illustrating different examples and aspects of the invention. It should be appreciated that the scope of the invention includes other embodiments not discussed in detail above. For example, the approaches described above can be applied to the integration of functional devices other than LEDs and OLEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present invention can be implemented in, using, or with the assistance of a computer program product, such as a storage medium (media) or computer readable storage medium (media) having instructions stored thereon/in which can be used to program a processing system to perform any of the features presented herein. The storage medium can include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present invention can be incorporated in software and/or firmware for controlling the hardware of a processing system, and for enabling a processing system to interact with other mechanisms utilizing the results of the present invention. Such software or firmware may include, but is not limited to, application code, device drivers, operating systems, and execution environments/containers.

It will be understood that, although the terms “first,” “second,” etc. may be used herein to describe various elements or steps, these elements or steps should not be limited by these terms. These terms are only used to distinguish one element or step from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art to best utilize the invention and the various embodiments.

1. A micro LED panel including a micro LED array, comprising a plurality of micro LED structures, wherein each of the plurality of micro LED structures comprises:
a mesa structure, comprising a first type epitaxial layer, a light emitting layer, and a second type epitaxial layer from bottom to top; and
a photonic crystal structure array comprising a plurality of photonic crystal structures, each photonic crystal structure of the plurality of photonic crystal structures being formed through the mesa structure from top to bottom, and a gap being between adjacent photonic crystal structures of the plurality of photonic crystal structures.

2. The micro LED panel according to claim 1, wherein:
a top of the plurality of photonic crystal structures is aligned with a top of the mesa structure; and
a bottom of the plurality of photonic crystal structures is aligned with a bottom of the mesa structure.

3. The micro LED panel according to claim 1, wherein;
each photonic crystal structure is a one-dimensional nano-structure; and
the one-dimensional nano-structure is formed perpendicular to the light emitting layer and along a light emitting direction of the mesa structure.

4-5. (canceled)

6. The micro LED panel according to claim 3, wherein:
a diameter of the one-dimensional nano-structure is less than or equal to about 1000 nm; and
a width of the mesa structure is less than or equal to about 3 μm.

7. (canceled)

8. The micro LED panel according to claim 1, wherein a dielectric layer is filled in the gap between adjacent photonic crystal structures of the plurality of photonic crystal structures.

9. The micro LED panel according to claim 8, wherein the dielectric layer is further formed on a sidewall of the mesa structure.

10. (canceled)

11. The micro LED panel according to claim 8, wherein the dielectric layer is transparent and electrically isolated.

12. (canceled)

13. The micro LED panel according to claim 1, wherein the light emitting layer comprises a plurality of stacked pairs of quantum wells.

14. The micro LED panel according to claim 1, wherein a cross section of the light emitting layer has a straight line shape without bending.

15. The micro LED panel according to claim 1, wherein;
a material of the first type epitaxial layer is monocrystal; and
a material of the second type epitaxial layer is monocrystal.

16. The micro LED panel according to claim 1, wherein:
a top contact is formed on and electrically connected to a top of the mesa structure; and
a top conductive layer is formed on the top contact and the top of the mesa structure.

17. The micro LED panel according to claim 16, wherein the top conductive layer is transparent.

18-84. (canceled)

85. The micro LED panel according to claim 1, wherein:
the plurality of photonic crystal structures comprise a center photonic crystal structure, each of rest photonic crystal structures of the plurality of photonic crystal structures being formed around the center photonic crystal structure.

86. The micro LED panel according to claim 85, wherein:
each of the plurality of micro LED structures further comprises a top contact, formed on top of the center photonic crystal structure; and
a diameter of the center photonic crystal structure is greater than a diameter of each of rest photonic crystal structures of the plurality of photonic crystal structures.

87-165. (canceled)

166. The micro LED panel according to claim 1, wherein:
a bottom contact layer is formed at a bottom of the mesa structure;
a bottom connected layer is formed at a bottom of the bottom contact layer; and
a space is formed between adjacent micro LED structures of the plurality of micro LED structures.

167. The micro LED panel according to claim 166, wherein a bottom surface of the space is aligned with a bottom surface of the bottom connected layer.

168. The micro LED panel according to claim 166, wherein a bottom surface of the space is aligned with a top surface of the bottom contact layer.

169. The micro LED panel according to claim 166, wherein a dielectric layer is fully filled in the space.

170. The micro LED panel according to claim 16, wherein the top conductive layer is continuously formed on an entirety of a top surface of the micro LED panel.

171. The micro LED panel according to claim 16, wherein the top conductive layer covers a part of a top surface of the mesa structure.
